(19) United States
(12) Patent Application Publication
(10) Pub. No.: US 2025/0253973 A1
(43) Pub. Date: Aug. 7, 2025

(54) SYSTEMS AND METHODS FOR COMMUNICATION AND SENSING IN MULTI-STATIC SENSING

(71) Applicant: HUAWEI TECHNOLOGIES CO., LTD., SHENZHEN (CN)

(72) Inventors: Yan XIN, Kanata (CA); Rui DU, Kanata (CA); Osama ABOUL-MAGD, Kanata (CA); Jung Hoon SUH, Kanata (CA); Kwok Shum AU, Kanata (CA)

(73) Assignee: HUAWEI TECHNOLOGIES CO., LTD., SHENZHEN (CN)

(21) Appl. No.: 19/186,158

(22) Filed: Apr. 22, 2025

Related U.S. Application Data
(63) Continuation of application No. PCT/CN2023/098826, filed on Jun. 7, 2023.

(51) Int. Cl. H04L 1/00; H03M 13/00; H03M 13/25

(52) U.S. Cl. CPC H04L 1/0007; H03M 13/255; H03M 13/6527; H04L 1/0003; H04L 1/0009

(57) ABSTRACT

Apparatus, methods and systems for communication and sensing in multi-static sensing may be provided. According to an aspect a method 800 for transmitting a multistatic sensing PPDU may be provided. The method 800 includes generating, by processing electronics in an initiator 801, a multistatic sensing PPDU 804. The multistatic sensing PPDU 804 may be an IEEE 802.11 multistatic sensing PPDU, e.g., PPDU 300. The IEEE 802.11 multistatic sensing PPDU may include a data field, a sync field following the data field, a training field (TRN) following the sync field, and a PSDU Length field included in an EDMG-Header-A of the PPDU. The PSDU Length field may be set by the apparatus to have a value according to particular described equations and specifications.

### CROSS-REFERENCE TO RELATED APPLICATION

This application is a continuation of International Patent Application No. PCT/CN2023/098826, filed on Jun. 7, 2023, and titled “Systems and Methods for Communication and Sensing in Multi-Static Sensing”, the content of which is incorporated herein by reference in its entirety.

### TECHNICAL FIELD

The present disclosure pertains to the field of to the field of radio communications and radio-based object sensing, and in particular to methods and systems for communication and sensing in a multi-static (or multistatic) sensing application.

### BACKGROUND

The Enhanced Directional Multi Gigabit (EDMG) multi-static sensing physical layer protocol data unit (PPDU) structure is defined in the draft 802.11bf standard Section 28.9.3, IEEE P802.11bf/D1.0 (Institute of Electrical and Electronics Engineers (IEEE). published January 2023, IEEE P802.11bf/D1.0. [Online] available: https://www.ieee802.org/11/private/index.shtml). To ensure coexistence and backward compatibility between the new 802.11bf compliant stations (STAs) and the legacy EDMG STAs, a legacy EDMG STA is required to detect the preambles of a transmitted EDMG multi-static sensing PPDU and understand the duration of the whole EDMG multi-static sensing PPDU. However, currently, a legacy EDMG STA cannot decode payload data and cannot understand the Sync field carried in an EDMG multi-static sensing PPDU. Accordingly, a legacy EDMG STA may be unable to adequately detect the preambles and understand the duration of the whole EDMG multi-static sensing PPDU. That is, it has not to date been established how a legacy STA can properly know certain required parameters of the multi-static sensing PPDU for coexistence and backward compatibility.

Therefore, there is a need for methods and systems for communication and sensing in multi-static sensing that obviates or mitigates one or more limitations of the prior art.

This background information is provided to reveal information believed by the applicant to be of possible relevance to the present invention. No admission is necessarily intended, nor should be construed, that any of the preceding information constitutes prior art against the present invention.

### SUMMARY

Apparatus, methods and systems for communication and sensing in multi-static sensing may be provided. According to an aspect, an apparatus in an IEEE 802.11 EDMG station (STA) may be provided. The apparatus may include including processing electronics configured to generate an IEEE 802.11 multistatic sensing PPDU for transmission. As used herein, generating may be replaced with providing, where it is understood that the providing is performed by an originating entity. Processing electronics may refer to a processor or other suitable electronic circuitry. The IEEE 802.11 multistatic sensing PPDU may include a data field, a sync field following the data field, a training field (TRN) following the sync field, and a PSDU Length field included in an EDMG-Header-A of the PPDU. The PSDU Length field may be set by the apparatus to have a value equal to

$$LENGTH = ⌊ {N}_{CW} \cdot \frac{{L}_{CW}}{ρ} \cdot R / 8 ⌋ ,$$

where the brackets represent a floor function rounding down to the nearest integer. The apparatus may allow for legacy EDMG STAs to interpret the duration of the Data field and Sync field in EDMG multi-static sensing PDDU. The apparatus may allow for a legacy EDMG STA to properly interpret and determine the duration of an EDMG multi-static sensing PPDU. The apparatus may allow for transmission of both data and sensing signals while maintaining backward compatibility and coexistence with legacy EDMG STAs.

A value of Length set in PSDU Length field in EDMG Header A may be expressed in octets. The N_{CW} may be determined according to: N_{CW}=└(512−N_{GI})×N_{blk}×N_{CBPS}×N_{CB}/L_{CW}┘. L_{CW} may be a specified low density parity check (LDPC) codeword length for the PPDU. ρ may be a specified repetition factor for the PPDU. R may be a specified code rate for the PPDU. N_{GI} may be a number of symbols in each one of a plurality of guard intervals interspersed with symbol blocks of the data field. N_{GI} may be directly specified in GI Length field in L-Header in 802.11ay.

N_{blk} may be a total number of single carrier (SC) symbol blocks with the same duration as a combination of the data field and the sync field. N_{blk} may be calculated by the apparatus, where the apparatus is a transmitter. The value of N_{blk} may be not transmitted. N_{CBPS} may be a number of coded bits per constellation symbol and is determined based on a specified modulation and coding scheme (MCS) for the PPDU. N_{CB} may be a number of channels bonded together to create a single channel used for transmission of the PPDU.

The sync field may have a length, measured in symbols, given by: N_SYM_SYNC_SENS=N_STA×L_SYNC×128+N_pad_SYM. Accordingly, N_SYM_SYNC_SENS=N_blk_SYNC×512. N_STA may be a number of EDMG multistatic sensing stations (STAs) to which the multistatic sensing PPDU is transmitted. L_SYNC may be a number of Golay sequences in each of N_STA sync subfields of the sync field. N_pad_SYM may be a number of symbols in a sync pad subfield of the sync field. N_blk_SYNC may be a number of SC symbol blocks having a duration equivalent to a duration of the sync field.

N_pad_SYM may correspond to an integer number of Golay sequences, an integer number of Golay sequences plus a part of a Golay sequence, or another number of symbols. The sync field may include N_STA sync subfields. Each N_STA sync subfield may include L_SYNC Golay sequences without internal padding. The sync field may further include a sync pad subfield which is not necessarily an integer number of Golay sequences. The sync field may be configured to have a total length which is an integer multiple of 512 single carrier symbols. The sync field may be configured to have a duration which is equivalent to the duration of an integer multiple of 512 single carrier symbols.

Some or all of L_{CW}, ρ, R and the MCS may be specified in the EDMG-Header-A. The sync field may include multiple sync subfields each for use by a different respective one of a plurality of EDMG multistatic sensing STAs to which the corresponding sync subfield and TRN field in multistatic sensing PPDU is transmitted. The sync field may further include a sync pad subfield following the multiple sync subfields.

For context and greater certainty, the PPDU may include, contiguously in order: an L-STF field, an L-CEF field, an L-Header, the EDMG-Header-A field, an EDMG-STF field, an EDMG-CEF field, the data field, the sync field, and the TRN field. N_{GI} may equal to 64. N_{GI} may be specified by a GI length field of an L-Header field of the PPDU.

Correspondence between N_{CBPS} and the MCS may include some or all of the following: N_{CBPS} equals 1 when the MCS is binary phase shift keying (BPSK) modulation, or N_{CBPS} equals 2 when the MCS is quadrature phase shift keying (QPSK) modulation, or N_{CBPS} equals 4 when the MCS is 16-state quadrature amplitude modulation (16-QAM). MCS may be a setting for a combination of a code rate, a modulation type and a repetition type.

According to another aspect, an apparatus in an IEEE 802.11 EDMG station (STA) may be provided. The apparatus may include processing electronics configured to generate an IEEE 802.11 multistatic sensing PPDU for transmission. The IEEE 802.11 multistatic sensing PPDU may include a data field carrying a number EDMG_LENGTH of octets of useful data (e.g. PSDU data) and a number DATA_PAD_LENGTH of zero or more octets of data padding added to the useful data. The IEEE 802.11 multistatic sensing PPDU may further include a sync field following the data field having a same duration as a field carrying a length of SYNC_LENGTH data as measured in octets. The IEEE 802.11 multistatic sensing PPDU may further include a PSDU Length field included in an EDMG-Header-A of the PPDU. The PSDU Length field may be set by the apparatus to have a value equal to: LENGTH=EDMG_LENGTH+DATA_PAD_LENGTH+SYNC_LENGTH The number DATA_PAD_LENGTH may be set such that a number of codewords N_CW2 carried in the data field is an integer value, the codewords carried in the data field being generated based on the octets of useful data and the octets of data padding and the codewords carried in the data field being subsequently modulated. The apparatus may allow for a legacy EDMG STA to interpret the duration of the Data field and the Sync field in a EDMG multi-static sensing PPDU as equivalent to the duration of Data field in an EDMG PPDU. The apparatus may allow for backward compatibility and coexistence of legacy EDMGs STAs with new 802.11bf compliant STAs. The apparatus may allow for transmission of both data and sensing signals while maintaining backward compatibility and coexistence with legacy EDMG STAs.

The number DATA_PAD_LENGTH may be a minimum value among possible values set such that a number of codewords N_CW2 carried in the data field is an integer value. The N_CW2 may have a value in accordance with:

$${N}_{CW 2} = \frac{( EDMG\_LENGTH + DATA\_PAD \_LENGTH ) \cdot 8}{\frac{{L}_{CW}}{ρ} \cdot R} .$$

L_{CW} may be a specified low density parity check (LDPC) codeword length for the PPDU. ρ may be a specified repetition factor for the PPDU. R may be a specified code rate for the PPDU. One, some or all of L_{CW}, ρ and R may be specified in the EDMG-Header-A.

The length SYNC_LENGTH as measured in octets may specify an equivalent number of octets which, upon encoding and modulation in a same manner as octets of the data field, may result in a (integer) number of single carrier symbol blocks which has the same duration as the sync field.

The sync field may include a number N_SYM_SYNC_SENS of modulation symbols and the number N_SYM_SYNC_SENS relates to the length SYNC_LENGTH via equations:

$$N\_SYM \_SYNC \_SENS = N\_blk \_SYNC \times 512 ;$$

$${N}_{CW\_SYNC} = ⌊ ( 512 - {N}_{GI} ) \times N\_blk \_SYNC \times N\_CBPS \times {N}_{CB} / {L}_{CW} ⌋ ; and$$

$$SYNC\_LENGTH = ⌊ {N}_{CW\_SYNC} \cdot \frac{{L}_{CW}}{ρ} \cdot R / 8 ⌋ .$$

L_{CW} may be a specified low density parity check (LDPC) codeword length for the PPDU. ρ may be a specified repetition factor for the PPDU. R may be a specified code rate for the PPDU. N_{GI} may be a number of symbols in each one of a plurality of guard intervals interspersed with SC symbol blocks of the data field. N_{CBPS} may be a number of coded bits per constellation symbol and is determined based on a specified modulation and coding scheme (MCS) for the PPDU. N_{CB} may be a number of channels bonded together to create a single channel used for transmission of the PPDU. One, some or all of L_{CW}, ρ, R and the MCS may be specified in the EDMG-Header-A.

N_{GI} may be set to equal 64. N_{GI} may be specified by a GI length field of an L-Header field of the PPDU.

According to another aspect, an apparatus in an IEEE 802.11 EDMG station (STA) may be provided. The apparatus may include processing electronics configured to generate an IEEE 802.11 multistatic sensing PPDU for transmission. The IEEE 802.11 multistatic sensing PPDU may include a data field carrying a number EDMG_LENGTH of data octets. The IEEE 802.11 multistatic sensing PPDU may further include a sync field following the data field and having a same duration as a field carrying a length of SYNC_LENGTH data as measured in octets. The sync field may include a number of Sync subfields and a Sync_PAD subfield with N_pad_SYM of padding symbols. The IEEE 802.11 multistatic sensing PPDU may further include a PSDU Length field included in an EDMG-Header-A of the PPDU. The PSDU Length field may be set by the apparatus to have a value equal to: LENGTH=EDMG_LENGTH+SYNC_LENGTH.

The length SYNC_LENGTH may be related to the number N_pad_SYM via equations:

$$N\_blk \_SYNC = ( TRN\_BL \times 18 \times N\_STA + N\_pad \_SYM ) / 512 ;$$

$${N}_{CW\_SYNC} = ( 512 - {N}_{GI} ) \times N\_blk \_SYNC \times N\_CBPS \times {N}_{CB} / {L}_{CW} ; and$$

$$SYNC\_LENGTH = {N}_{CW\_SYNC} \cdot \frac{{L}_{CW}}{ρ} \cdot R / 8.$$

The number N_pad_SYM may be set such that SYNC_LENGTH is an integer value. The TRN_BL may be a specified value indicative of a length of Golay sequences used in the PPDU. N_STA may be a number of EDMG multistatic sensing stations (STAs) to which the multistatic sensing PPDU is transmitted. L_{CW} may be a specified low density parity check (LDPC) codeword length for the PPDU. ρ may be a specified repetition factor for the PPDU. R may be a specified code rate for the PPDU. N_{GI} may be a number of symbols in each one of a plurality of guard intervals interspersed with symbol blocks of the data field. N_{CBPS} may be a number of coded bits per constellation symbol and is determined based on a specified modulation and coding scheme (MCS) for the PPDU. N_{CB} may be a number of channels bonded together to create a single channel used for transmission of the PPDU. The apparatus may allow for a legacy EDMG STA to interpret the duration of the Data field and the Sync field in a EDMG multi-static sensing PPDU as equivalent to the duration of Data field in an EDMG PPDU. The apparatus may allow for a legacy EDMG STA to determine the duration of an EDMG multi-static sensing PPDU (for example so that it can operate appropriately during such duration). The apparatus may allow for backward compatibility and coexistence of legacy EDMGs STAS with new 802.11bf compliant STAs.

One, some or all of L_{CW}, ρ, R and the MCS may be specified in the EDMG-Header-A. TRN_BL may be indicated by a TRN subfield sequence length field the EDMG-Header-A. The padding symbols may be located in a sync pad subfield forming a last part of the sync field. The number N_pad_SYM is a minimum value among possible values set such that the length SYNC_LENGTH is an integer value.

The length SYNC_LENGTH as measured in octets may specify an equivalent number of octets which, upon encoding and modulation in a same manner as octets of the data field, would result in a number of modulated symbols having a total duration equivalent to a duration of the sync field.

N_{GI} may equal to 64. N_{GI} may be specified by a GI length field of an L-Header field of the PPDU.

According to another aspect, another apparatus in an IEEE 802.11 EDMG station (STA) may be provided. The apparatus may include processing electronics configured to initiate transmission of some TXVECTOR parameters through a multistatic sensing setup phase. The TXVECTOR parameters may indicate characteristics of an associated IEEE 802.11 multistatic sensing PPDU to be interpreted by other STAs participating in a multistatic sensing operation involving the IEEE 802.11 multistatic sensing PPDU. The processing electronics may further be configured to separately initiate transmission of the IEEE 802.11 multistatic sensing PPDU. The IEEE 802.11 multistatic sensing PPDU may have a PSDU Length field set such that another IEEE 802.11 EDMG STA unaware of the multistatic sensing will interpret a combination of a data field and a sync field of the IEEE 802.11 multistatic sensing PPDU to be a single data field. The apparatus may, via provisions of TXVECTOR parameters, allow for legacy EDMG STAs to interpret the duration of Data field and Sync field in EDMG multi-static sensing PDDU. The apparatus may allow for a legacy EDMG STA to determine the duration of an EDMG multi-static sensing PPDU. The apparatus may allow for backward compatibility and coexistence of legacy EDMGs STAs with new 802.11bf compliant STAs.

The TXVECTOR parameters may include a PSDU Length field, a MCS field, a short/long LDPC field, a N_CB field, a TRN_BL field, and a GI type field.

According to another aspect, an IEEE 802.11 EDMG STA may be provided that includes the processing electronics to generate a multistatic sensing PPDU according to one or more aspects described herein. The STA may further include other components such as an antenna, radiofrequency electronics, radiofrequency front end, etc.

According to another aspect, a system may be provided that includes an IEEE 802.11 EDMG STA, and one or more EDMG multistatic sensing STAs to which a multistatic sensing PPDU is transmitted. The multistatic sensing PPDU may be include one or more fields according to one or more aspects described herein.

According to another aspect, a method, performed by the processing electronics for an IEEE 802.11 EDMG station (STA) may be provided. The method includes generating an IEEE 802.11 multistatic sensing PPDU for transmission according to one or more aspects. The IEEE 802.11 multistatic sensing PPDU may include one or more fields according to one or more aspects described herein. The method may include operations as described above with respect to one or more apparatuses.

According to another aspect, an apparatus is provided. The apparatus includes modules configured to perform one or more of the methods and systems described herein.

According to one aspect, an apparatus is provided, where the apparatus includes: a memory, configured to store a program; a processor, configured to execute the program stored in the memory, and when the program stored in the memory is executed, the processor is configured to perform one or more of the methods and systems described herein.

According to another aspect, a computer readable medium is provided, where the computer readable medium stores program code executed by a device and the program code is used to perform one or more of the methods and systems described herein.

According to one aspect, a chip is provided, where the chip includes a processor and a data interface, and the processor reads, by using the data interface, an instruction stored in a memory, to perform one or more of the methods and systems described herein. Aspects may further include the memory.

Other aspects of the disclosure provide for apparatus, and systems configured to implement the methods according to the first aspect disclosed herein. For example, wireless stations and access points can be configured with machine readable memory containing instructions, which when executed by the processors of these devices, configures the device to perform one or more of the methods and systems described herein.

Embodiments have been described above in conjunction with aspects of the present invention upon which they can be implemented. Those skilled in the art will appreciate that embodiments may be implemented in conjunction with the aspect with which they are described but may also be implemented with other embodiments of that aspect. When embodiments are mutually exclusive, or are incompatible with each other, it will be apparent to those skilled in the art. Some embodiments may be described in relation to one aspect, but may also be applicable to other aspects, as will be apparent to those of skill in the art.

### BRIEF DESCRIPTION OF THE DRAWINGS

Further features and advantages of the present invention will become apparent from the following detailed description, taken in combination with the appended drawings, in which:

FIG. 1 illustrates an example of EDMG multi-static sensing setup 100 with one transmitter and two receivers.

FIG. 2 illustrates a procedure of EDMG multi-static sensing.

FIG. 3 illustrates a format of an EDMG multi-static PPDU, including a data field and a sync field.

FIG. 4 illustrates a sync subfield 400 of an EDMG multi-static sensing PPDU.

FIG. 5 illustrates data field 500 in an EDMG PPDU.

FIG. 6 illustrates a procedure of coding, modulation and symbol blocking of data field in EDMG SC PPDU.

FIG. 7 illustrates an apparatus 700, such as a IEEE 802.11 STA, that may perform any or all of operations of the above methods and features explicitly or implicitly described herein, according to different aspects of the present disclosure.

FIG. 8 illustrates a method for transmitting a multistatic sensing PPDU, according to an aspect.

FIG. 9 illustrates a procedure for coding a Data field in an EDMG multi-static sensing PPDU, according to an aspect.

FIG. 10 illustrates a procedure for coding a Data field in an EDMG PPDU, according to an aspect.

FIG. 11 illustrates a sync subfield where N_CB=1, for use in understanding embodiments of the disclosure.

FIG. 12 illustrates equivalent duration of sync subfield in EDMG multi-static sensing PPDU and symbol blocks in EDMG PPDU, for use in understanding embodiments of the disclosure.

FIG. 13 illustrates another method for transmitting a multistatic sensing PPDU, according to an aspect.

FIG. 14 illustrates another method for transmitting a multistatic sensing PPDU, according to an aspect.

FIG. 15 illustrates a method of multi-static sensing, according to an aspect.

It will be noted that throughout the appended drawings, like features are identified by like reference numerals.

### DETAILED DESCRIPTION

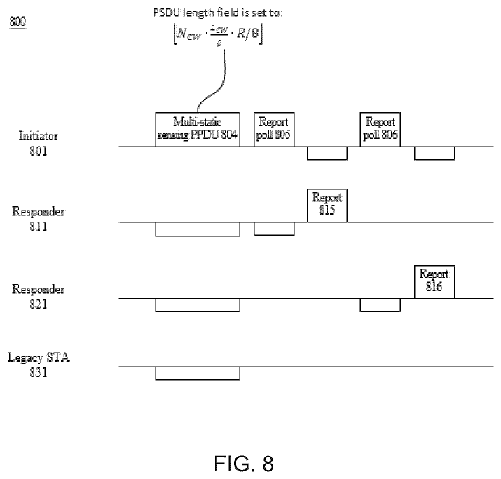

Apparatus, methods and systems for communication and sensing in multi-static sensing may be provided. According to an aspect, and referring to FIG. 8, a method 800 for transmitting a multistatic sensing PPDU may be provided. The method 800 includes generating, by processing electronics in an initiator 801, a multistatic sensing PPDU 804. The multistatic sensing PPDU 804 may be an IEEE 802.11 multistatic sensing PPDU, e.g., PPDU 300. The IEEE 802.11 multistatic sensing PPDU may include a data field, a sync field following the data field, a training field (TRN) following the sync field, and a PSDU Length field included in an EDMG-Header-A of the PPDU. The PSDU Length field may be set such that sum of a duration of the data field and the sync filed in the multistatic sensing PPDU is equivalent to a duration of a data field in an EDMG PPDU (i.e. the multistatic sensing PPDU treated as a non-sensing EDMG PPDU), where the EDMG PPDU has an indicated total duration equivalent to that of the multistatic sensing PPDU. In some embodiments, the PSDU length may be set by the apparatus to have a value according to Equation (10), e.g.,

$$LENGTH = ⌊ {N}_{CW} \cdot \frac{{L}_{CW}}{ρ} \cdot R / 8 ⌋$$

where N_{CW} may be derived from a sum of a duration of the data field and the sync field in a multistatic sensing PPDU.

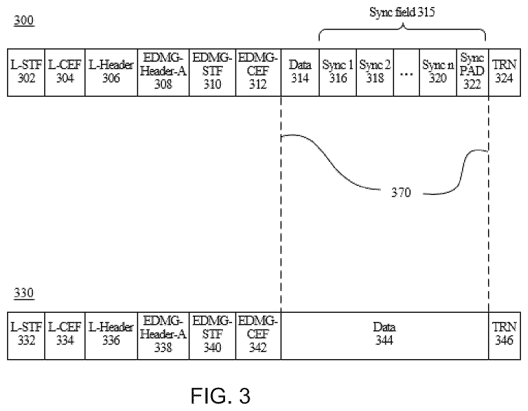

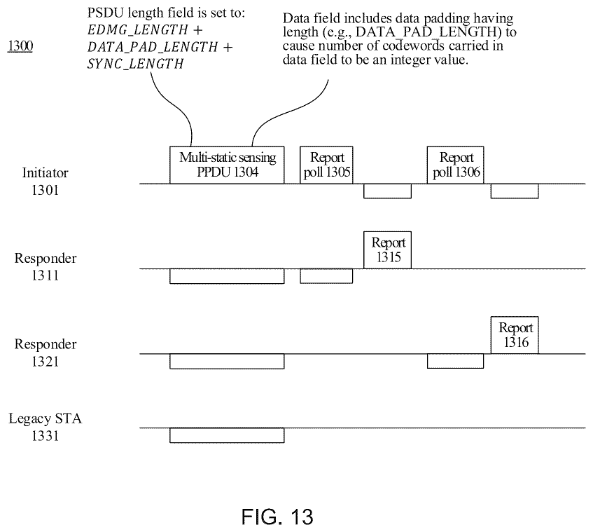

According to another aspect, and referring to FIG. 13, another method 1300 for transmitting a multistatic sensing PPDU may be provided. The method 1300 includes generating, by processing electronics in an initiator 1301, a multistatic sensing PPDU 1304. The multistatic sensing PPDU 1304 may be an IEEE 802.11 multistatic sensing PPDU, e.g., PPDU 300 of FIG. 3. The IEEE 802.11 multistatic sensing PPDU may include a data field carrying a number EDMG_LENGTH of octets of PSDU data and a number DATA_PAD_LENGTH of zero or more octets of data padding added to the PSDU data. PSDU data may refer to data carrying information to be decoded and used, and may also be referred to in some cases as “useful” data. The IEEE 802.11 multistatic sensing PPDU 1304 may further include a sync field following the data field having a same duration as a field carrying a length of SYNC_LENGTH data as measured in octets. The IEEE 802.11 multistatic sensing PPDU 1304 may further include a PSDU Length field included in an EDMG-Header-A of the PPDU. The PSDU Length field may be set by the apparatus to have a value equal to: LENGTH=EDMG_{LENGTH}+DATA_{PAD}_{_{LENGTH}}+SYNC_{LENGTH}. The number DATA_PAD_LENGTH may be set such that a number of codewords N_CW2 carried in the data field is an integer value, the codewords carried in the data field being generated based on the octets of PSDU data and the octets of data padding and the codewords carried in the data field being subsequently modulated.

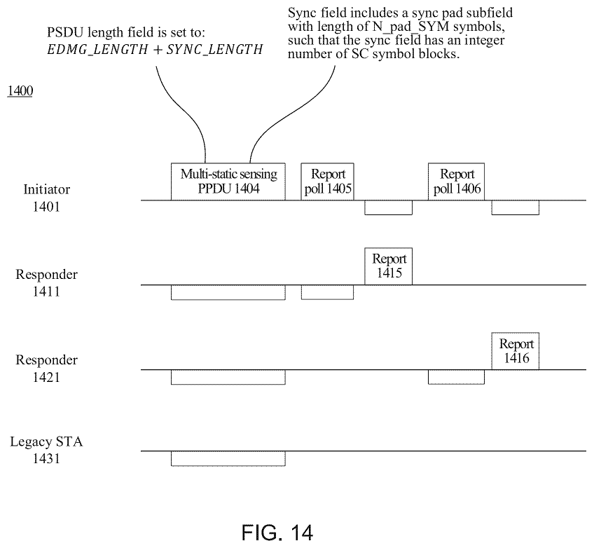

According to another aspect, and referring to FIG. 14, another method 1400 for transmitting a multistatic sensing PPDU may be provided. The method 1400 includes generating, by processing electronics in an initiator 1401, a multistatic sensing PPDU 1404. In some embodiments, the multistatic sensing PPDU 1404 may be an IEEE 802.11 multistatic sensing PPDU, e.g., PPDU 300. The IEEE 802.11 multistatic sensing PPDU 1404 may include a data field carrying a number EDMG_LENGTH of data octets. The IEEE 802.11 multistatic sensing PPDU 1404 may further include a sync field following the data field and having a same duration as a field carrying a length of SYNC_LENGTH data as measured in octets. The sync field may include a number of Sync subfields and a Sync_PAD subfield with N_pad_SYM of padding symbols. The IEEE 802.11 multistatic sensing PPDU 1404 may further include a PSDU Length field included in an EDMG-Header-A of the PPDU. The PSDU Length field may be set by the processing electronics (e.g., a processor) within the initiator 1401 to have a value equal to: LENGTH=EDMG_LENGTH+SYNC_LENGTH.

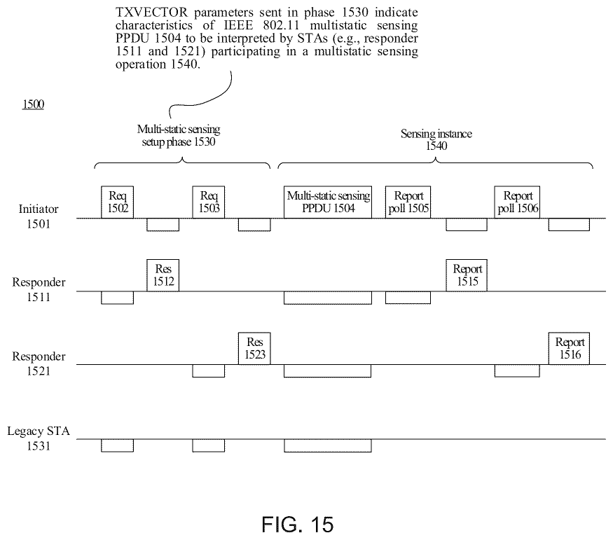

According to another aspect, and referring to FIG. 15, a method 1500 of multi-static sensing may be provided. The method 1500 includes, initiating, by processing electronics (e.g., a processor) at initiator 1501, transmission of some TXVECTOR parameters through a multi-static sensing setup phase 1530. The TXVECTOR parameters may indicate characteristics of an associated IEEE 802.11 multistatic sensing PPDU 1504 to be interpreted by other STAs (e.g., responder 1511 and 1521) participating in a multistatic sensing operation 1540 involving the IEEE 802.11 multistatic sensing PPDU 1504. The method 1500 may further include separately initiating, by the processing electronics at initiator 1501, transmission of the IEEE 802.11 multistatic sensing PPDU 1504. The IEEE 802.11 multistatic sensing PPDU 1504 may have a PSDU Length field set such that another IEEE 802.11 EDMG STA unaware of the multistatic sensing will interpret a combination of a data field and a sync field of the IEEE 802.11 multistatic sensing PPDU 1504 to be a single data field. The method 1500 may allow for a legacy EDMG STA to understand the duration of an EDMG multi-static sensing PPDU. The method may further allow for a legacy EDMG STA to interpret the duration of the Data field and the Sync field in an EDMG multi-static sensing PPDU as equivalent to the duration of Data field in an EDMG PPDU. The method may further allow for transmission of both data and sensing signals while maintaining backward compatibility and coexistence with legacy EDMG STAS.

The Enhanced Directional Multi Gigabit (EDMG) multi-static sensing physical layer protocol data unit (PPDU) structure is defined in the draft 802.11bf standard Section 28.9.3, IEEE P802.11bf/D1.0. To ensure coexistence and backward compatibility between the new 802.11bf compliant stations (STAs) and the legacy EDMG STAs, a legacy EDMG STA is required to detect the preambles of a transmitted EDMG multi-static sensing PPDU and understand the duration of the whole EDMG multi-static sensing PPDU. However, a legacy EDMG STA may not be able to fully decode payload data and in particular may not be able to decode, parse or understand contents of the Sync field carried in an EDMG multi-static sensing PPDU. For reasons of coexistence, a legacy EDMG STA may be required to adequately detect the preambles and understand (or determine) the duration of the whole EDMG multi-static sensing PPDU. Embodiments of the present disclosure facilitate such a requirement.

The 802.11bf standard is currently under development in IEEE 802.11 Task Group bf for enhancement of Wireless LAN Sensing. As described in the Project Authorization Request (PAR) of the 802.11bf project 802.11-19/2103r12, the scope of this project is to “define modifications to the IEEE 802.11 medium access control layer (MAC) and to the Directional Multi Gigabit (DMG) and enhanced DMG (EDMG) PHYs to enhance Wireless Local Area Network (WLAN) sensing (SENS) operation in license-exempt frequency bands between 1 GHz and 7.125 GHz and above 45 GHz.”

DMG sensing is currently categorized into: (coordinated) monostatic, (coordinated) bistatic and multi-static sensing. One or more aspects of this disclosure pertain to multi-static sensing, in which one PPDU is transmitted from one sensing initiator to multiple sensing responders.

The EDMG multi-static sensing PPDU structure is defined in the draft 802.11bf standard Section 28.9.3, IEEE P802.11bf/D1.0, which specifies that “The PSDU Length field and the EDMG MCS field shall be set to values such that the duration of the Data field, as interpreted from the EDMG-A Header of the PPDU (see 28.12.3.3 (TXTIME calculation for EDMG SC mode), IEEE P802.11-REV me/D2.1) by an EDMG STA unaware of the Multi-static Sensing is equal to the duration of the Data field plus the duration of the Sync field (see 28.12.3.3 (TXTIME calculation for EDMG SC mode)) in the EDMG multi-static sensing PPDU.”

However, as described in Section 28.12.3.3, IEEE P802.11-REV me/D2.1], calculation of TXTIME involves not only PSDU Length and EDMG MCS in EDMG-Header-A, which are related to the Data field in multi-static sensing PPDU, but also other TXVECTOR parameters specified in preamble fields such as the Guard Interval (GI) length in L-Header as well as the TRN_Seq_Length (i.e., the Golay seq. length in TRN) in EDMG-Header-A, which are related to the SYNC field in multi-static sensing PPDU. Thus, fulfilling the requirement is not straightforward.

If a PPDU includes a data field, in an EDMG-Header-A, a PHY layer service data unit (PSDU) Length field may be set to specify a total length of the data field, plus each one of the one or more SYNC fields, plus the SYNC Pad field. However, IEEE 802.11bf D1.0 is unclear regarding how to set PSDU Length field in EDMG-Header-A and how to set other TXVECTOR parameters in the fields of multi-static PPDU preamble.

According to an aspect, the construction of Data and Sync fields in multi-static sensing PPDU may be described and provided. According to an aspect, one or more methods on how to set the preamble fields in order to transmit both data and sensing signals in a single PPDU may be provided. According to an aspect, backward compatibility and coexistence with the existing EDMG WLAN STAs may be maintained.

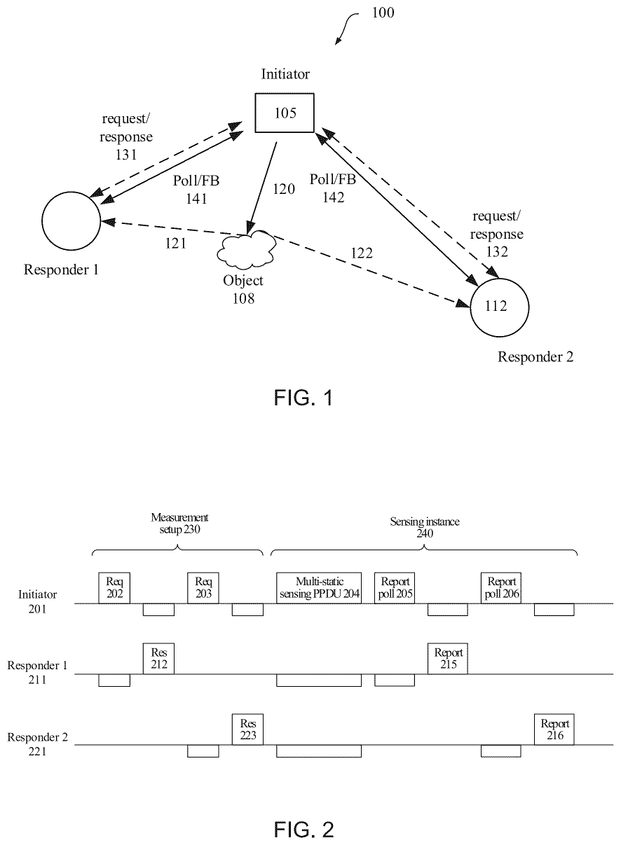

EDMG multi-static sensing is described in IEEE P802.11bf/D1.0 and an example of EDMG multi-static sensing is illustrated in FIG. 1. FIG. 1 illustrates an example of EDMG multi-static sensing setup 100 with one transmitter and two receivers.

The transmitter and the receivers may each be STAs on a wireless communication network. The multi-static sensing setup 100 is illustrated with TWO receivers but may also be generalized to include more than two receivers.

In the multi-static sensing setup 100, the sensing initiator 105 (e.g., an access point (AP)) begins to send the multistatic sensing requests acting a transmitter to each of two (for example) sensing responders 111, 112 acting as receivers and then each responder acting a transmitter sends its response back to the initiator acting a receiver. The sensing instance may be set up by an exchange of request and response 131 (handshakes) with the first responder 111, and a similar exchange of request and response 132 with the second responder 112.

The sensing instance may generally be directed towards detecting features of a given target, such as object 108. The sensing instance includes the sensing initiator 105 transmitting a sounding PPDU. A part of the signal 120, particularly one or more training (TRN) fields in the sounding PPDU, from the sensing initiator 105 may be transmitted from the sensing initiator 105 and strike the object 108. A part of this signal 121 may reflect off the object 108 and propagate towards the first responder 111, and a part of this signal 122 may reflect off the object 108 and propagate towards the second responder 112. After the sensing initiator 105 transmits the sounding PPDU, each of the responders 111, 112 may be polled and report feedback 141, 142. The feedback 141, 142 may be related to the part of the signal 121, 122 which was received by the responders 111, 112 after it had reflected off the object 108. The feedback 141, 142 may be used by the sensing initiator 105 to detect features of the object 108.

FIG. 2 illustrates a procedure of EDMG multi-static sensing. Before the sensing instance phase 240, the initiator 201 and one or more responders 211 and 221 may undergo a sensing measurement setup phase 230 in which the initiator sends a multi-static sensing request 202 and 203 to each responder 211 and 221 respectively. Each responder 211 and 221 may send its response 212 and 223, respectively, back to the initiator 201. The measurement setup phase 230 may correspond to the handshake 131 and 132 of FIG. 1. In the measurement setup up phase, information related to one or both of sensing capabilities and sensing operation of the initiator 201 and the responders 211 and 221 is exchanged through transmission of the requests and the responses.

In the sensing instance phase 240 a single EDMG multi-static sensing PPDU 204 may be transmitted from the initiator 201 to multiple responders 211 and 221. The format of EDMG multi-static sensing PPDU is shown in FIG. 3. After sensing measurement is conducted by the responders, the initiator may poll each responder and each responder may send back measurement reports. For example, initiator 201 may send the report poll request 205 to the first responder 211 which will send a report 215 to the initiator 201. The initiator 201 may send the report poll request 206 to the second responder 221 which will send the report 216 to the initiator 201. Other approaches for polling and reporting are also possible.

FIG. 3 illustrates a format of an EDMG multi-static PPDU 300. The EDMG multi-static PPDU 300 may include one or more of: a legacy short training field (L-STF) 302, a legacy channel estimation field (L-CEF) 304, an L-Header field 306, an EDMG-Header-A field 308, an EDMG-STF 310, an EDMG-CEF 312, a data field 314, a sync field 315 (comprising one or more of: sync subfields 316, 318, 320, a sync PAD subfield 322) and a training (TRN) field 324. Each of the one or more sync subfields 316, 318, and 320 may correspond to a respective a multi-static sensing responder (receiver). The EDMG multi-static PPDU 300 may be based on the EDMG multi-static PPDU defined in IEEE P802.11bf/D1.0.

FIG. 3 also illustrates a format of an EDMG PPDU 330. The EDMG PPDU 330 may include one or more of: an L-STF 332, an L-CEF 334, an L-Header field 336, an EDMG-Header-A field 338, an EDMG-STF 340, an EDMG-CEF 342, a data field 344, and a TRN field 346. FIGS. 3A and 3B are aligned such that the EDMG PPDU 330 may be viewed as a legacy EDMG STA's interpretation of the multi-static sensing PPDU 300. Notably, the data field 314 and the sync field 315, including its subfields, of the multi-static sensing PPDU 300 is interpreted by the legacy STA as a single general data field 344 without any identified parts or subfields.

The L-STF 332 allows discovery and synchronization of the EDMG/DMG packet, while the L-CEF 334 enables channel estimation for demodulation of the L-Header field 336 and the EDMG-Header-A field 338. The L-Header field 336 contains information about the EDMG/DMG packet. The EDMG-Header-A field 338 contains information for the EDMG PPDU. The EDMG-STF 340 allows synchronization of the EDMG PPDU. The EDMG-CEF 342 allows channel estimation for demodulation of the data field 344. The data field 344 includes the payload data of the packet, padded with zeros if necessary for packaging. The TRN sequence field 346 which is used for beam forming training and beam tracking, as part of a beam refinement protocol (BRP) process to allow STAs to improve their antenna configuration for transmission and/or reception. The TRN field 346 may be composed of a plurality of TRN subfields, as may be described in the EDMG standard.

With respect to the EDMG multi-static sensing PPDU 300, the L-STF 302 is a non-EDMG Short Training field as in the EDMG PPDU 330. The L-CEF 304 is a Non-EDMG Channel Estimation field as in EDMG PPDU 330. The L-Header 306 is a non-EDMG Header field as in EDMG PPDU 330. The EDMG-Header-A 308 is an EDMG Header A field modified from the EDMG-Header-A field 338 in EDMG PPDU 330. The EDMG-STF 310 is an EDMG-STF EDMG Short Training field as in EDMG PPDU 330. The EDMG-CEF 312 is an EDMG Channel Estimation field as in EDMG PPDU 330. The Data field 314 carries the PSDU(s) as in EDMG PPDU 330 but possibly with different padding. The sync subfields 314, 316 and 320 and the Sync PAD subfield 322 are new in the EDMG multi-static sensing PPDU 300. The one or more sync subfields 314, 316 and 320 are described in Section 28.9.3.4.2, IEEE P802.11bf/D1.0. The TRN field 324 is modified from the TRN field 346 in EDMG PPDU 330.

As may be appreciated, a legacy EDMG STA cannot decode payload data and cannot understand the Sync field 315 carried in an EDMG multi-static sensing PPDU 300. In more detail, when receiving a multistatic sensing PPDU, the legacy STA may operate assuming the data field includes a data field carrying EDMG Length data and a field carrying sync Length data. This may cause errors when the receiver recovers data. However, because the new 802.11bf compliant STAs and the legacy EDMG STAs are required to coexist, the (legacy) EDMG STAs are required to be able to detect the preambles of a transmitted EDMG multi-static sensing PPDU and understand the duration of the whole EDMG multi-static sensing PPDU.

The document IEEE P802.11bf/D1.0 specifies that “The PSDU Length field and the EDMG MCS field shall be set to values such that the duration of the Data field, as interpreted from the EDMG-A header of the PPDU by a legacy EDMG STA unaware of the Multi-static Sensing is equal to the duration of the Data field plus the duration of the Sync field” for a legacy EDMG STA to understand the duration of EDMG multi-static sensing PPDU.” This is illustrated via lines 370 in FIG. 3, where the duration of the data field 344 of EDMG PPDU 330 is equal to the duration of the data field 314 plus the duration of the sync field 315 (comprising the one or more sync subfields 316, 318 and 320, and the Sync PA D subfield 322).

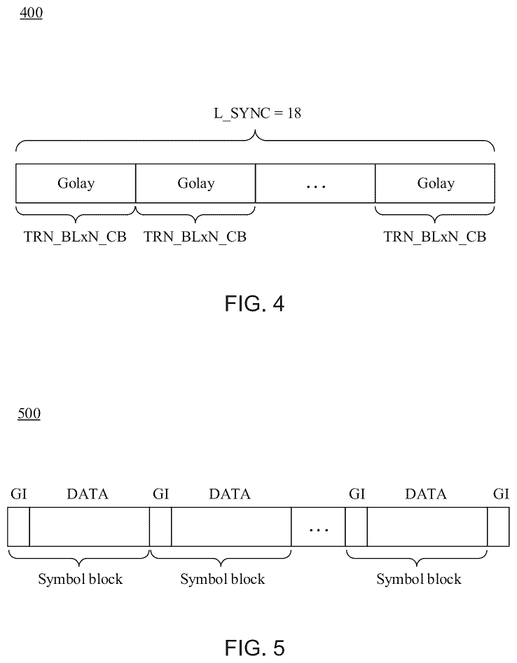

As shown in the multi-static PPDU format 300, the Sync field 315 may be composed of one or more (N_STA>=1) Sync subfields 316, 318 and 320, each of which may be defined for a specific STA. The Sync field 315 may further include a Sync PAD subfield 322 following the one or more Sync subfields. Each Sync subfield include L_SYNC=18 Golay sequences of length TRN_BL×N_CB as shown in FIG. 4. FIG. 4 illustrates a sync subfield 400 of an EDMG multi-static sensing PPDU. The sync subfield 400 may refer to any of the one or more subfields 316, 318 and 320 of the EDMG multi-static sensing PPDU 300. Each Golay sequence in FIG. 4 has length TRN_BL times N_CB.

According to an aspect, as discussed above, a (legacy) EDMG STA unaware of EDMG multi-static sensing may interpret the duration of Data field 314 plus Sync field 315 in an EDMG multi-static sensing PPDU 300 as the duration of Data field 344 in an EDMG PPDU 330. According to embodiments of the present disclosure, the GI type field in L-Header and the PSDU length, the MCS and the TRN subfield Sequence Length fields in EDMG-Header-A may be specified so as to enable the EDMG STA, unaware of EDMG multi-static sensing, to interpret the duration of Data field plus Sync field in EDMH multi-static sensing PPDU as the duration of Data field in EDMG PPDU.

As may be appreciated, in order to be backward-compatible to any EDMG STA, the preamble parameters in the EDMG multi-static sensing PPDU, which are related to interpretation of Data field duration in EDMG PPDU, should be specified as those supporting the EDMG mandatory features.

The Sync PAD subfield 320 may be composed of N_pad (>=1) Golay sequences of length TRN_BL×N_CB such that (TRN_BL/128)×(N_pad+N_STAT×L_SYNC) is the smallest integer that is greater than or equal to (TRN_BL/128)×N_STA×L_SYNC and is a multiple of 4 (implying that the duration of Sync field 315 including Sync subfields and Sync PAD subfield is equal to the duration of an integer number of SC symbol blocks).

As may be appreciated, the TRN subfield Sequence Length field in EDMG-Header-A [Table 28-12, IEEE P802.11-REV me/D2.1] may be: set to 0 to indicate 128×N_CB (i.e., TRN_BL=128); set to 1 to indicate 256×N_CB (i.e., TRN_BL=256); and set to 2 to indicate 64×N_CB (i.e., TRN_BL=64).

According to an aspect, duration of Data and Sync fields in EDMG multi-static sensing PPDU 300 [based on Section 28.12.3.3, IEEE P802.11bf/D1.0] may be calculated.

According to one or more aspects, several solutions may be provided regarding how to set the PSDU Length in EDMG multi-static sensing PPDU in order to ensure that the combined duration of Data field, T_DATA_SENS, and the duration of Sync field, T_SYNC_SENS, in an EDMG multi-static sensing PPDU 300 is equivalent to the duration of Data field in an EDMG PPDU, T_DATA, i.e.:

$$T\_DATA = T\_DATA \_SENS + T\_SYNC \_SENS$$

$$T\_DATA = ( N\_blk \_DATA \times 512 + N\_GI ) \times aDMGChipTimeDuration + ( N\_STA \times L\_SYNC + N\_pad ) \times T\_Golay$$

Referring to the above equation, N_blk is the number of SC symbol blocks calculated based on the PSDU data carried in EDMG multi-static sensing PPDU. N_STA is the number of EDMG multi-static sensing STAs to which the EDMG multi-static sensing PPDU is transmitted. T_Golay=128×aDMGChipTimeDuration, N_pad and L_SYNC (=18) are as described herein in reference to Section 28.9.3.4.3 of IEEE P802.11bf/D1.0

Although the total duration of Data field plus Sync field in EDMG multi-static sensing PPDU is specified, how to set the PSDU Length field in EDMG-Header-A, which corresponds to the total duration of Data field plus Sync field in EDMG multi-static sensing PPDU, is yet to be determined.

Mandatory features of an EDMG STA may be based on Section 28.1.1 of IEEE P802.11-REV me/D2.1 (IEEE, published January 2023, IEEE P802.11-REV me/D2.1. [Online] available: https://www.ieee802.org/11/private/index.shtml). The EDMG STA shall support two carrier bandwidths (N_CB) for transmission and reception of data: 2.16 GHz (N_CB=1) and 4.32 GHZ (N_CB=2). The EDMG STA shall support PPDU transmission and reception using EDMG SC mode MCSs 1 to 5 and 7 to 10 for both 2.16 GHz and 4.32 GHz carrier bandwidths.

The EDMG STA shall support single spatial stream transmission and reception in all channel widths that the EDMG STA supports. The EDMG STA shall use Normal GI type, with a GI length of 64 when N_CB=1 and 128 when N_CB=2. The duration of mandatory GI length is fixed.

The modulation used in MCS 1 to 5 and 7 to 10 can be Binary Phase Shift Keying (BPSK) with N_CBPS=1 or Quadrature Phase Shift Keying (QPSK) with N_CBPS=2. The code rate can be 1/2, 5/8, 3/4, or 13/16.

The TRN subfield definition for EDMG SC PPDUs may refer to 28.9.2.2.6 TRN, IEEE P802.11-REV me/D2.1. The TRN field should have Golay sequences of length 128 and 256 in TRN field (i.e., TRN_BL equal to 128 and N_CB equal to 1 or 2). The duration of a mandatory Golay sequence is fixed.

The duration of an EDMG SC PPDU in EDMG SC mode may be based on 28.12.3.3 TXTIME calculation for EDMG SC mode, IEEE P802.11-REV me/D2.1. TXTIME calculation may be as follows:

$$TXTIME = T\_L - STF + T\_LTF + T\_L - Header + T\_EDMG - Header - A + T\_EDMG - STF + T\_EDMG - CEF + T\_DATA + T\_TRN$$

Data field transmission in EDMG PPDU may be based on Section 20.5.3.2.5 Symbol blocking and guard insertion; and Section 28.5.2.2 Timing-related parameters, IEEE P802.11-REV me/D2.1. FIG. 5 illustrates a data field 500 of an EDMG PPDU. The duration of the data field 500 may be determined by the number of symbol blocks required to transmit the data. The data field 500 includes plural symbol blocks separated from one another by guard intervals GI.

In an EDMG PPDU (see Section 28.3.3.3.2.3 of IEEE P802.11-REV me/D2.1), the duration of Data field T_DATA is related to number of symbol blocks (determined by PSDU length and MCS specified in EDMG-Header-A and GI length specified in L-Header in EDMG PPDU (see Section 28.3.3.2.4 L-Header definition, IEEE P802.11-REV me/D2.1)).

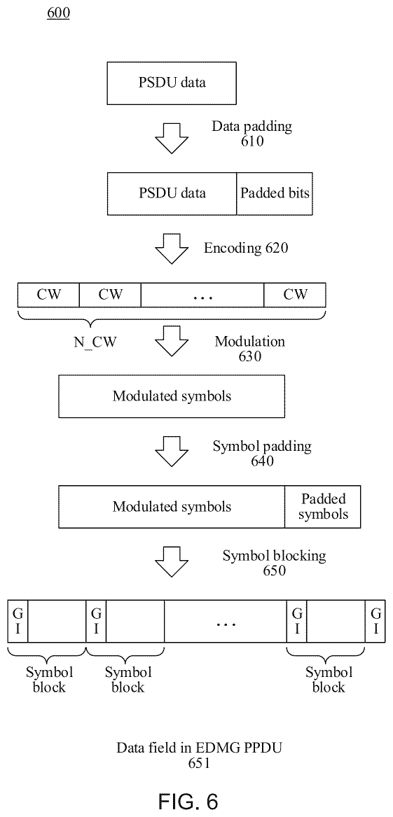

FIG. 6 illustrates a procedure of coding, modulation and symbol blocking of data field in EDMG SC PPDU. The procedure 600 may be based on procedure of PSDU data encoding, modulation and symbol blocking in EDMG SC PPDU (see Section 28.5.9.4, IEEE P802.11-REV me/D2.1).

As illustrated, to generate data field 651 in an EDMG PPDU, according to procedure 600, PSDU data may be padded 610 with bits and encoded 620 to generate a number N_CW of codewords CW. The N_CW codewords may be modulated 630 to generate modulated symbols and further padded 640 with symbols to generate modulated symbols with padded symbols. The modulated symbols with padded symbols may further undergo symbol blocking 650 (e.g. separation into multiple blocks separated by guard intervals) to determine the number of symbol blocks for the data field.

Before encoding 620 PSDU data, the transmitter calculates the number of codewords, according to:

$${N}_{CW} = ⌊ \frac{PSDU\_LENGTH \cdot 8}{\frac{{L}_{CW}}{ρ} \cdot R} ⌋ \qquad ( 1 )$$

Determining the pad bits for padding 610 PSDU data to make an integer number of codewords may be based on:

$${N}_{DATA , PAD} = {N}_{CW} \cdot \frac{{L}_{CW}}{ρ} \cdot R - PSDU\_LENGTH \cdot 8 \qquad ( 2 )$$

Referring to the above equations, the PSDU_LENGTH, L_{CW}, ρ, and R are the PSDU length, codeword length, repetition factor (1 or 2 (for MCS 2 only)) and code rate, respectively. All of these parameters may be specified in EDMG-Header-A in an EDMG PPDU.

After encoding and modulation, the modulated data symbols are allocated into symbol blocks, each of which includes 512-N_GI symbols where the modulation type is specified by MCS defined in EDMG-Header-A and GI Length is defined in L-Header in EDMG PPDU, respectively. Then, symbol padding is performed to yield an EDMG PPDU with an integer number of symbol blocks.

The text specified in IEEE P802.11bf/D1.0 on how to set the PSDU Length field and the EDMG MCS field in EDMG-Header-A in an EDMG multi-static sensing PPDU is not sufficient from an implementation perspective. As described in Section 28.12.3.3, IEEE P802.11-REV me/D2.1, calculation of TXTIME involves not only PSDU Length and EDMG MCS in EDMG-Header-A, but also other preamble fields (TXVECTOR parameters) such as GI length in L-Header as well as BW (bandwidth) or N_{CB} (number of bonded channels) and TRN_Seq_Length (i.e., Golay seq. length in TRN) in EDMG-Header-A.

The procedure specified in IEEE P802.11bf/D1.0 for setting Sync PAD subfield considers symbol blocking only, based on which an EDMG STA may still be unable to calculate the total duration of Data field plus Sync field in EDMG multi-static sensing PPDU.

As specified in draft 802.11bf Section 28.9.3, IEEE P802.11bf/D1.0, the value of the PSDU Length field in EDMG-Header-A of EDMG multi-static PPDU is related to the calculation of both the duration of Data field and the duration of Sync field, which includes the corresponding data length and sync length, respectively.

A legacy EDMG STA may calculate the N_CW and N_(DATA, PAD) based on the combined data length and sync length specified in the PSDU Length field. In addition, the Data field in an EDMG multi-static sensing PPDU, which also carries data information, should be constructed from an integer number of codewords. Furthermore, the Sync PAD subfield is defined at a symbol level in EDMG multi-static PPDU. Not having the Sync PAD subfield involved in the coding and modulation process of the Data field may be preferable.

The procedure of coding, modulation and symbol blocking for generation of an EDMG PPDU, in reference to FIG. 6, includes two steps of padding. The first step of padding is data padding 610, which is performed to generate an integer number of codewords. The second step of padding is symbol padding 640, which is performed to construct the Data field of the EDMG PPDU to be composed of an integer number of symbol blocks. A legacy EDMG STA may be unable to conduct data padding and symbol padding for the separated Data field and Sync field respectively.

One or more aspects may provide for setting PSDU Length values and the corresponding construction of Data field and Sync field in EDMG multi-static sensing.

One or more aspects may apply or be related to the standardization of IEEE 802.11bf on construction of EDMG multi-static sensing PPDU. One or more aspects may apply to Wi-Fi APs and STAs with capability of DMG sensing.

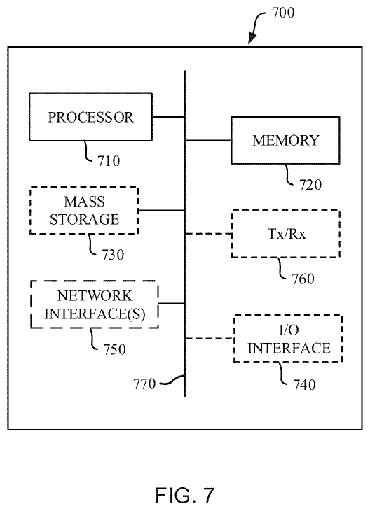

FIG. 7 illustrates an apparatus 700 that may perform any or all of operations of the above methods and features explicitly or implicitly described herein, according to different aspects of the present disclosure. For example, a computer equipped with network function may be configured as the apparatus 700. In some aspect, apparatus 700 can be a device that connects to the network infrastructure over a radio interface, such as a mobile phone, smart phone or other such device that may be classified as user equipment (UE). In some aspects, the apparatus 700 may be a Machine Type Communications (MTC) device (also referred to as a machine-to-machine (m2m) device), or another such device that may be categorized as a UE despite not providing a direct service to a user. In some aspects, apparatus 700 may be used to implement one or more aspects described herein. In some embodiments, the apparatus 700 may be a user equipment (UE), an AP, a STA, an initiator, a transmitter, a receiver, a responder or the like as appreciated by a person skilled in the art. The AP (or STA) can operate to transmit or receive a PPDU as described herein, for example in support of multi-static sensing.

As shown, the apparatus 700 may include a processor 710, such as a Central Processing Unit (CPU) or specialized processors such as a Graphics Processing Unit (GPU) or other such processor unit, memory 720, non-transitory mass storage 730, input-output interface 740, network interface 750, and a transceiver 760, all of which are communicatively coupled via bi-directional bus 770. Transceiver 760 may include one or multiple antennas According to certain aspects, any or all of the depicted elements may be utilized, or only a subset of the elements. Further, apparatus 700 may contain multiple instances of certain elements, such as multiple processors, memories, or transceivers. Also, elements of the hardware device may be directly coupled to other elements without the bi-directional bus. Additionally, or alternatively to a processor and memory, other electronics or processing electronics, such as integrated circuits, application specific integrated circuits, field programmable gate arrays, digital circuitry, analog circuitry, chips, dies, multichip modules, substrates or the like, or a combination thereof may be employed for performing the required logical operations.

The memory 720 may include any type of non-transitory memory such as static random-access memory (SRAM), dynamic random-access memory (DRAM), synchronous DRAM (SDRAM), read-only memory (ROM), any combination of such, or the like. The mass storage element 730 may include any type of non-transitory storage device, such as a solid-state drive, hard disk drive, a magnetic disk drive, an optical disk drive, USB drive, or any computer program product configured to store data and machine executable program code. According to certain aspects, the memory 720 or mass storage 730 may have recorded thereon statements and instructions executable by the processor 710 for performing any method operations described herein.

Embodiments of the present disclosure provide for setting of a value in PSDU Length field in EDMG multi-static PPDU to facilitate a legacy EDMG STA to interpret that the summation of the duration of data field and the sync field in EDMG multistatic sensing PPDU is equivalent to the duration of data field in an EDMG PPDU with the same TXTIME.

According to an aspect, define value T_DATA follows:

$$T\_DATA = T\_DATA \_SENS + T\_SYNC \_SENS \qquad ( 3 )$$

$$T\_DATA = ( N\_SYM \_DATA \_SENS + N\_SYM \_SYNC \_SENS ) \times aDMGChipTimeDuration$$

T_DATA may refer to the duration of a data field 344 of an EDMG PPDU as interpreted by a legacy EDMG STA, which is equal to the duration T_DATA_SENS of the data field 314 plus the duration of the sync field 315 (FIGS. 3A and 3B). Values N_SYM_DATA_SENS and N_SYM_SYNC_SENS are, correspondingly, the integer number of symbols in the DATA field 314 and the Sync field 315 in the multi-static sensing PPDU, respectively.

According to an aspect, the Data field and Sync field may be constructed, according to a first case, as in Section 28.12.3.3, IEEE802.11bf D1.0, i.e.:

$$N\_SYM \_DATA \_SENS = N\_blk \_DATA \times 512 + N\_GI \qquad ( 4 )$$

$$N\_SYM \_SYNC \_SENS = ( N\_STA \times L\_SYNC + N\_pad ) \times 128$$

$$N\_SYM \_SYNC \_SENS = N\_blk \_SYNC \times 512 \qquad ( 5 )$$

According to another aspect, the Data field and Sync field may be constructed, according to a second case, as follows:

$$N\_SYM \_DATA \_SENS = N\_blk \_DATA \times 512 + N\_GI \qquad ( 6 )$$

$$N\_SYM \_SYNC \_SENS = N\_STA \times L\_SYNC \times 128 + N\_pad \_SYM$$

$$N\_SYM \_SYNC \_SENS = N\_blk \_SYNC \times 512$$

where N_pad_SYM symbols can be an integer number of Golay sequences, an integer number of Golay sequences plus a partial Golay sequence, or a number of any other symbols. It should be noted that this second case has not heretofore been suggested. Accordingly, embodiments of the present disclosure provide for methods and apparatus which involve construction of the data field and the sync field in this manner. For example, according to embodiments, the sync field includes N_STA sync subfields each comprising L_SYNC Golay sequences. These sync subfields may be without internal padding (e.g. padding symbols added to each sync subfield). The sync field further includes a sync pad subfield which is not necessarily an integer number of Golay sequences. The sync field may be further configured to have a total length which is an integer multiple of 512 or another suitable value. Additionally or alternatively, the sync field may be configured to have a duration which is equivalent to the duration of an integer multiple of 512 single carrier symbols, or another suitable value. For example, each Sync subfield may include only L_SYNC Golay sequences of length 128. Currently in the draft IEEE standard, the Sync_PAD subfield is required to be an integer number of Golay sequences of length 128. However, it is anticipated by the inventors that this requirement may be too strict and may lead to inefficiencies in padding and setting the PSDU_Length in the Header. Thus, the described alternative is provided.

According to an aspect, the value to be set in PSDU Length field may be determined. The PSDU length field value may be determined as follows. The total number of SC symbols blocks in both EDMG multistatic sensing PPDU and EDMG PPDU may equal (assuming that the same N_GI is applied to both types of PPDU):

$$N\_blk = N\_blk \_DATA + N\_blk \_SYNC \qquad ( 7 )$$

The number of data symbols after coding and modulation, which is calculated based on the value set in the PSDU Length field, may equal:

$$N\_SYM = ( 512 - N\_GI ) \times N\_blk \qquad ( 8 )$$

As may be appreciated, in EDMG, N_GI=64 may be mandatory. Therefore, the number of data symbols in each SC symbol block may equal 448 (=512-64). Here and elsewhere, 448 may be replaced with 512-N_GI and vice-versa.

The number of codewords in the equivalent Data field in EDMG PPDU may then be:

$${N}_{CW} = ⌊ ( 512 - {N}_{GI} ) \times {N}_{blk} \times {N}_{CBPS} \times {N}_{CB} / {L}_{CW} ⌋ \qquad ( 9 )$$

Where, N_CBPS may be determined by MCS; L_CW is LDPC codeword length; MCS, N_CB and L_CW are specified EDMG-Header-A.

In some embodiments, N_pad_SYM for Sync padding, under the second case in reference to equation (6), maybe the smallest integer to provide for a minimized N_CW.

The value in PSDU Length field may be set according to:

$$LENGTH = ⌊ {N}_{CW} \cdot \frac{{L}_{CW}}{ρ} \cdot R / 8 ⌋ \qquad ( 10 )$$

where MCS, N_CB, L_CW, ρ, and R are as defined herein.

FIG. 8 illustrates a method for transmitting a multistatic sensing PPDU, according to an aspect associated with Equation (10). The method 800 includes generating, by processing electronics in an initiator 801, a multistatic sensing PPDU 804. The processing electronics may refer to a processor for example. The processing electronics and the initiator 801, may each be based on the apparatus 700. In some embodiments the initiator 801 may be an IEEE 802.11 EDMG station (STA).

The method 800 may further include sending, by the initiator 801, the generated multi-static sensing PPDU 804 to one or more responders 811 and 821. A legacy STA 831 may also receive the multi-static sensing PPDU 804, but may ignore the contents of the PPDU after processing header information and determining that the PPDU is to be ignored. Since a legacy EDMG STA, can detect the EDMG-Header-A, it can understand the TXTIME (total duration) of the PPDU. If the data decoding fails or the detection of MAC header content identifies a wrong destination ID, the legacy STA may step into a power saving mode until the end of the received PPDU.

The method my further include sending to a first responder 811 a report poll 805 and receiving from the first responder 811 a first report 815. The method further includes sending, by initiator 801 to the second responder 821 a second report poll 806 and receiving from the second responder 821 a second report 816.

As may be appreciated, the duration of a multistatic sensing PPDU (e.g., PPDU 804) may be a sum of some durations of preambles (L-STF, L-LTF, L-Header, EDMG STF, EDMG-LTF) and variable durations of Data and TRN fields. Therefore, the duration of an EDMG sensing multistatic PPDU 804 may not only relate to PSDU Length setting, but also other parameters may be involved. The PPDU 804, including such detail, may be similar to the PPDUs 1304, 1404 and 1504 in this respect, as described elsewhere herein with respect to FIGS. 13, 14 and 15.

In some embodiments, the multistatic sensing PPDU 804 may be an IEEE 802.11 multistatic sensing PPDU, e.g., PPDU 300. The IEEE 802.11 multistatic sensing PPDU may include a data field, a sync field following the data field, a training field (TRN) following the sync field, and a PSDU Length field included in an EDMG-Header-A of the PPDU. The PSDU Length field may be set such that sum of a duration of the data field and the sync filed in the multistatic sensing PPDU is equivalent to a duration of a data field in an EDMG PPDU, where the EDMG PPDU has a total duration equivalent to that of the multistatic sensing PPDU. In some embodiments, the PSDU length may be set by the apparatus to have a value according to Equation (10), e.g.,

$$LENGTH = ⌊ {N}_{CW} \cdot \frac{{L}_{CW}}{ρ} \cdot R / 8 ⌋ .$$

The method may allow for a legacy EDMG STA 831 to interpret the duration of Data field and Sync field in EDMG multi-static sensing PDDU 804 as the duration of Data field 344 in EDMG PPDU 330. The method may further allow for a legacy EDMG STA 831 to understand the duration of an EDMG multi-static sensing PPDU 804. The method may further allow for transmission of both data and sensing signals while maintaining backward compatibility and coexistence with legacy EDMG STAs.

In some embodiments, a value of Length set in PSDU Length field in EDMG Header A may be expressed in octets. The N_{CW} may be determined according to equation (9), e.g., N_{CW}=└(512−N_{GI})×N_{blk}×N_{CBPS}×N_{CB}/L_{CW}┘. L_{CW} may be a specified low density parity check (LDPC) codeword length for the PPDU. ρ may be a specified repetition factor for the codewords in the PPDU. R may be a specified code rate for the PPDU. N_{GI} may be a number of symbols in each one of a plurality of guard intervals interspersed with symbol blocks of the data field. N_{GI} may be directly specified in GI Length field in L-Header in 802.11ay.

N_{blk} may be a total number of single carrier (SC) symbol blocks with the same duration as a combination of the data field and the sync field. N_{blk} may be calculated by the apparatus, where the apparatus is a transmitter. In some embodiments, the value of N_{blk} may be not transmitted. N_{CBPS} may be a number of coded bits per constellation symbol and is determined based on a specified modulation and coding scheme (MCS) for the PPDU. N_{CB} may be a number of channels bonded together as the operation spectrum used for transmission of the PPDU.

The sync field may have a length, measured in symbols, given by equation (6): N_SYM_SYNC_SENS=N_STA×L_SYNC×128+N_pad_SYM. Accordingly, N_SYM_SYNC_SENS=N_blk_SYNC×512. N_STA may be a number of EDMG multistatic sensing stations (STAs) to which the multistatic sensing PPDU 804 is transmitted. L_SYNC may be a number of Golay sequences in each of N_STA sync subfields of the sync field. N_pad_SYM may be a number of symbols in a sync pad subfield of the sync field. N_blk_SYNC may be a number of symbol blocks corresponding to the sync field.

N_pad_SYM may correspond to an integer number of Golay sequences, an integer number of Golay sequences plus a part of a Golay sequence, or another number of symbols.

In reference to N_{CB}, BW may be indicated in a BW field in EDMG-Header-A, which may be an 8-bit bit map. N_{CB}=1, where only 1 bit in the bit map equals ‘1’ and others are ‘0’. N_{CB}=2, where there are only two adjacent ‘1’s in the bit map and Channel Aggregation field in EDMG-Header-A is set to ‘0’. N_{CB}=2 may indicate that the number of bonded 2.16 GHz channels equals 2. Channel aggregation is to aggregate adjacent or non-adjacent channels while channel bonding requires adjacent channels to be bounded.

In some embodiments, some or all of L_{CW}, ρ, R and the MCS may be specified in the EDMG-Header-A. The sync field may include multiple sync subfields each for use by a different respective one of a plurality of EDMG multistatic sensing STAs to which the TRN field in multistatic sensing PPDU is transmitted. The sync field may further include a sync pad subfield following the multiple sync subfields.

In some embodiments, the PPDU 804 may include, contiguously in order: an L-STF field, an L-CEF field, an L-Header, the EDMG-Header-A field, an EDMG-STF field, an EDMG-CEF field, the data field, the sync field, and the TRN field. N_{GI} may be equal to 64. N_{GI} may be specified by a GI length field of an L-Header field of the PPDU.

Correspondence between N_{CBPS} and the MCS may include some or all of the following: N_{CBPS} equals 1 when the MCS is binary phase shift keying (BPSK), or N_{CBPS} equals 2 when the MCS is quadrature phase shift keying (QPSK), or N_{CBPS} equals 4 when the MCS is 16-state quadrature amplitude modulation (16-QAM). MCS may be a setting for a combination of a code rate, a modulation type and a repetition type.

According to another aspect, the method 800 may be performed by a system. The system may include an IEEE 802.11 EDMG STA (e.g., initiator 801), and one or more EDMG multi-static sensing STAs (responders 811 and 821) to which a multi-static sensing PPDU 804 is transmitted. The multi-static sensing PPDU 804 may include one or more fields according to one or more aspects described herein.

According to embodiments of the present disclosure, the PSDU Length field in an EDMG multi-static sensing PPDU 300 may be set to have a value according to:

$$LENGTH = DATA\_LENGTH + SYNC LENGTH \qquad ( 11 )$$

in which DATA_LENGTH and SYNC LENGTH may correspond to the Data field and Sync field, respectively. DATA_LENGTH may be further defined for example as in Equations (12) and (13) below. Such embodiments are described for example with respect to FIG. 13. In various such embodiments, the DATA_LENGTH in PSDU Length field in EDMG multi-static PPDU may be set to be EDMG_LENGTH+DATA_PAD_LENGTH. Furthermore, data of DATA_LENGTH can result in an exact integer number of codewords through an EDMG coding procedure satisfying Equation (13) described herein. This may facilitate backward compatibility with legacy EDMG STAS.

A legacy EDMG STA can calculate the separate N_CW based on the respective DATA_LENGTH and SYNC_LENGTH. In addition, the Data field in an EDMG multi-static sensing PPDU, which carries data information, should be composed of an integer number of codewords. It is desirable that DATA_LENGTH result in an exact integer number of codewords without further padding any data bits, which is interpreted by a legacy EDMG STA. Accordingly, in some embodiments, for a value in PSDU Length field, i.e., DATA_LENGTH+SYNC_LENGTH, padding data bits may be needed only for SYNC_LENGTH “data”, which is related to the Sync field.

Accordingly, the LENGTH value to be included in the PSDU Length field of the PPDU may be determined according to:

$$LENGTH = DATA\_LENGTH + SYNC\_LENGTH \qquad ( 12 )$$

$$LENGTH = ( EDMG\_LENGTH + DATA\_PAD \_LENGTH ) + SYNC\_LENGTH$$

Where EDMG_LENGTH is a TXVECTOR parameter indicating PSDU length in octets. DATA_PAD_LENGTH is the minimum value in length of PSDU data padding in octets, which can result in an exact integer number of codewords N_{CW2} through the EDMG encoding procedure.

Accordingly, N_{CW2} may be determined according to:

$${N}_{CW 2} = \frac{( EDMG\_LENGTH + DATA\_PAD \_LENGTH ) \cdot 8}{{L}_{CW} / ρ \cdot R} \qquad ( 13 )$$

Where SYNC_LENGTH is the length in octets, which is related to the SYNC field in EDMG multi-static sensing PPDU and used by a legacy EDMG receiver to interpret the duration of SYNC field in an EDMG multi-static sensing PPDU as an equivalent duration of a part of Data field in an EDMG PPDU.

According to an aspect, coding for Data field in EDMG multi-static sensing PPDU may be provided.

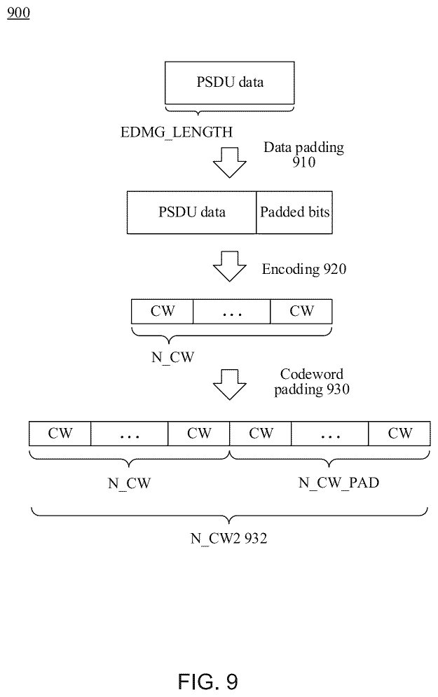

FIG. 9 illustrates a procedure for coding for a Data field in an EDMG multi-static sensing PPDU, according to an aspect. The procedure 900 includes applying data padding 910 to PSDU data to generate PSDU data with padded bits. The PSDU data may have a length of EDMG_LENGTH before padding.

The generated PSDU data with padded bits may undergo encoding 920 to generate N_CW codewords CW. In some embodiments, the encoding 920 may be based on the EDMG encoding procedure specified in 802.11ay to generate the N_CW codewords. The procedure 900 may further include performing codeword padding 930 to generate N_CW2 codewords 932. The codeword padding 930 may add N_CW_PAD additional codewords (such that N_CW_PAD=N_CW2−N_CW where N_CW2>N_CW). In some embodiments, equivalently, an EDMG STA can generate N_CW2 codewords with PSDU length set to be EDMG_LENGTH+DATA_PAD_LENGTH.

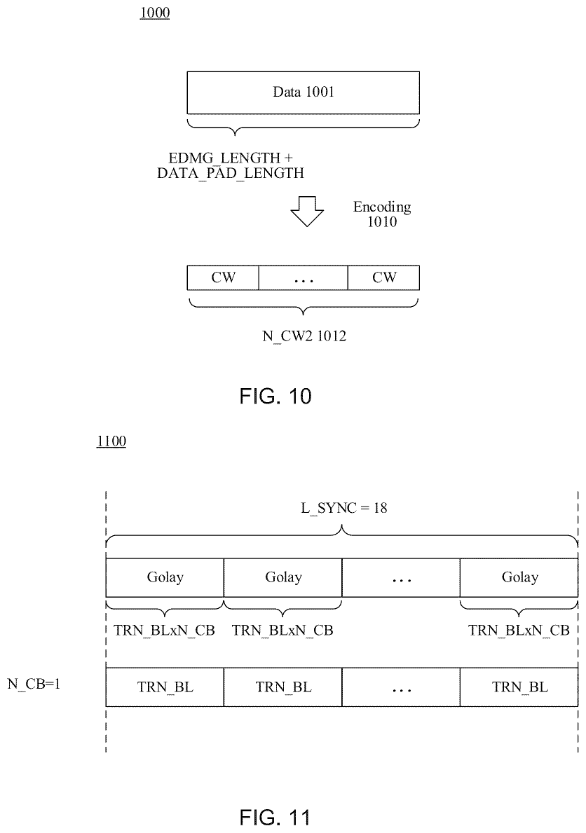

FIG. 10 illustrates a procedure of coding for Data field in an EDMG PPDU, according to an aspect. The procedure 1000 includes encoding 1010 the Data 1001 to generate N_CW2 codewords 1012. In some embodiments, the Data 1001 may have a length EDMG_LENGTH+DATA_PAD_LENGTH. In some embodiments, by following Eq. (13), an EDMG STA may generate N_CW2 codewords 1012 with PSDU length set as EDMG_LENGTH+DATA_PAD_LENGTH.

As may be appreciated, EDMG_LENGTH is a TXVECTOR parameter indicating the length of PSDU in octets. In EDMG, EDMG_LENGTH is the value set in PSDU Length field in EDMG-Header-A. However, in EDMG multi-static sensing PPDU, to spoof a legacy EDMG STA, the PSDU_LENGTH value set in PSDU Length field is different from EDMG_LENGTH.

According to an aspect, the Data field coding in EDMG multi-static sensing as illustrated in procedure 900 may be equivalent to the Data field coding in EDMG as illustrated in procedure 1000. The procedure 900 results in N_CW2 932 which may be equivalent to the N_CW2 1012 generated according to procedure 1000.

According to an aspect, the value SYNC_LENGTH in octets may be calculated based on the corresponding Sync field 315 in the EDMG multi-static sensing PPDU 300. The duration of Sync subfield+Sync_PAD subfield may equal to the duration of an integer number of symbol blocks N_blk_SYNC.

According to an aspect, in EDMG, the duration of TRN_BL×N_CB may be a constant for the mandatory parameter TRN_BL. The duration of each Golay sequence in Sync subfield may be equivalent to:

$$Duration of each Golay sequence = TRN\_BL \times aDMGChipTimeDuration \qquad ( 14 )$$

In some aspects, the duration of Sync field 315 may be equivalent to:

$$Duration of sync field = ( TRN\_BL \times 18 \times N\_STA + N\_pad \_SYM ) \times aDMGChipTimeDuration \qquad ( 15 )$$

The N_pad_SYM may be the number of symbols in Sync_PAD subfield 322. As may be appreciated, an EDMG STA may support TRN_BL=128, N_CB=1 or 2 only.

FIG. 11 illustrates a sync subfield where N_CB=1, according to an aspect. The sync subfield 1100 may be similar to the sync subfield 400. Sync subfield 1100 may comprise 18 Golay sequences, each sequence having a length TRN_BL×N_CB. In some embodiments, N_CB=1 such that the length of each Golay sequence is TRN_BL as illustrated.

According to an aspect, in EDMG, the duration of each symbol block may be constant and may be substantially irrelevant to N_CB and GI type. Therefore, each symbol block can be considered equivalently to include 64 GI symbols and 488 data symbols for N_CB=1. Accordingly, the duration of N_blk symbol blocks may be:

$$( 512 \times N\_blk \_SYNC ) \times aDMGChipTimeDuration \qquad ( 16 )$$

In some embodiments, an EDMG STA may support Normal GI type (i.e., GI=64) only.

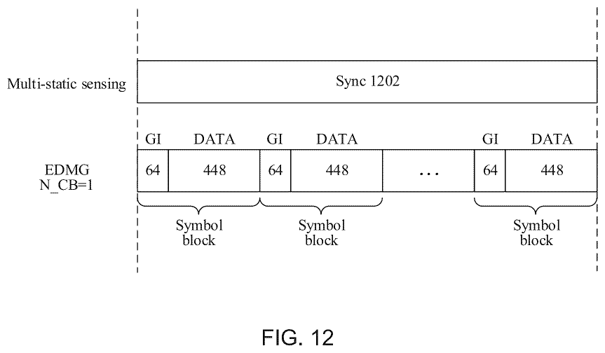

FIG. 12 illustrates equivalent duration of sync field 1202 in a EDMG multi-static sensing PPDU and symbol blocks in a regular EDMG PPDU (or as the multi-static sensing PPDU is interpreted by a legacy EDMG PPDU), according to an aspect. In an embodiment, the sync field 1202 may have a length equivalent to an integer number of symbol blocks (each comprising 448 DATA symbols and 64 GI symbols) in the EDMG PPDU, e.g., EDMG PPDU 330. The sync field 1202 may be equivalent to the sync field 315 of multi-static sensing PPDU 300 of FIG. 3.

According to an aspect, based on one or more information described (e.g., equations (14); (15); (16); in EDMG, the duration of TRN_BL×N_CB may be a constant for the mandatory parameter TRN_BL; and the duration of each symbol block may be constant and irrelevant to N_CB and GI type), the equivalent number of symbols blocks may be calculated as:

$$N\_blk \_SYNC = ( TRN\_BL \times 18 \times N\_STA + N\_pad \_SYM ) / 512 \qquad ( 17 )$$

The total number of equivalent data symbols corresponding to Sync field may be calculated as:

$$( 512 - N\_GI ) \times N\_blk \_SYNC \qquad ( 18 )$$

(Here, as elsewhere, 512−N_GI may be equal to 448.) The total number of equivalent coded data bits plus padded bits (translated from the padding symbols for symbol blocking) corresponding to Sync field may be calculated as:

$$( 512 - N\_GI ) \times N\_blk \_SYNC \times N\_CBPS \times N\_CB \qquad ( 19 )$$

where N_CBPS is the number of coded bits per constellation symbol, which is based on the specified MCS.

The number of equivalent codewords corresponding to Sync field maybe calculated as:

$${N}_{CW\_SYNC} = ⌊ ( 512 - {N}_{GI} ) \times N\_blk \_SYNC \times N\_CBPS \times {N}_{CB} / {L}_{CW} ⌋ \qquad ( 20 )$$

$${N}_{CW\_SYNC} = ⌊ 448 \times N\_blk \_SYNC \times N\_CBPS \times {N}_{CB} / {L}_{CW} ⌋ ,$$

$$where {N}_{GI} = 64 ;$$

where L_{CW} is LDPC codeword length and is specified in Short/Long LDPC field in EDMG-Header-A.

According to an aspect, the SYNC_LENGTH to be included in PSDU Length field, which corresponds to Sync field, may be calculated as:

$$SYNC\_LENGTH = ⌊ {N}_{CW\_SYNC} \cdot \frac{{L}_{CW}}{ρ} \cdot R / 8 ⌋ \qquad ( 21 )$$

According to an aspect, construction of Data field and Sync field in EDMG multi-static sensing PPDU may be provided.

A value in PSDU Length field in EDMG multi-static sensing PPDU may be specified as EDMG_LENGTH+DATA_PAD_LENGTH+SYNC_LENGTH in octets as considered in one more aspects herein.

EDMG_LENGTH PSDU data in octets and DATA_PAD_LENGTH padded data in octets may yield an integer number of codewords after encoding.

The SYNC_LENGTH “data” (calculated from Sync field in multi-static sensing PPDU) in octets may yield an integer number of symbol blocks.

According to an aspect, by following the procedure of EDMG coding, modulation and symbol blocking (EDMG_LENGTH+DATA_PAD_LENGTH+SYNC_LENGTH)×8 bits an equivalent Data field may be generated in an EDMG PPDU with the same duration as the duration of the Data field plus the duration of the Sync field in EDMG multi-static sensing PPDU, in which the Data field is composed of an integer number of symbols blocks and the duration of Sync field equals the duration of an integer number of symbols.

FIG. 13 illustrates a method for transmitting a multistatic sensing PPDU, according to an aspect in view of the above discussion. The method 1300 includes generating, by processing electronics in an initiator 1301, a multistatic sensing PPDU 1304. The processing electronics may refer to a processor for example. The processing electronics and the initiator 1301, may each be based on the apparatus 700.

The method 1300 may further include sending, by the initiator 1301, the generated multi-static sensing PPDU 1304 to one or more responders 1311 and 1321. A legacy STA 1331 may also receive the multi-static sensing PPDU 1304.

The method may further include sending to a first responder 1311 a report poll 1305 and receiving from the first responder 1311 a first report 1315. The method further includes, sending, by initiator 1301 to the second responder 1321 a second report poll 1306 and receiving from the second responder 1321 a second report 1316.

In some embodiments, the multistatic sensing PPDU 1304 may be an IEEE 802.11 multistatic sensing PPDU, e.g., PPDU 300. The IEEE 802.11 multistatic sensing PPDU may include a data field carrying a number EDMG_LENGTH of octets of PSDU data and a number DATA_PAD_LENGTH of zero or more octets of data padding added to the PSDU data. The IEEE 802.11 multistatic sensing PPDU 1304 may further include a sync field following the data field having a same duration as a field carrying a length of SYNC_LENGTH data as measured in octets. The IEEE 802.11 multistatic sensing PPDU 1304 may further include a PSDU Length field included in an EDMG-Header-A of the PPDU. The PSDU Length field may be set by the apparatus to have a value equal to: LENGTH=EDMG_{LENGTH}+DATA_{PAD}_{_{LENGTH}}+SYNC_{LENGTH}. The number DATA_PAD_LENGTH may be set such that a number of codewords N_CW2 carried in the data field is an integer value, the codewords carried in the data field being generated based on the octets of useful data and the octets of data padding and the codewords carried in the data field being subsequently modulated. The method may allow for legacy EDMG STAs, e.g., legacy STA 1331, to interpret the duration of Data field and Sync field in EDMG multi-static sensing PDDU 1304. The method may further allow for a legacy EDMG STA 1331 to understand the duration of an EDMG multi-static sensing PPDU 1304. The method may further allow for transmission of both data and sensing signals while maintaining backward compatibility and coexistence with legacy EDMG STAs.

It is noted that, in various embodiments, EDMG_LENGTH is a TXVECTOR parameter indicating the length of PSDU in octets. In EDMG, EDMG_LENGTH is the value set in PSDU Length field in EDMG-Header-A. However, in EDMG multistatic sensing PPDU, to spoof a legacy EDMG STA, the PSDU_LENGTH value set in PSDU Length field may be different from EDMG_LENGTH.

As may be appreciated, in 802.11bf, a legacy EDMG STA may be required to understand the total duration of a received multistatic sensing PPDU through the detected parameters such as the value in PSDU Length field, MCS, N_GI, N_CB set in the preambles. However, the EDMG STA cannot understand (decode) the sync field. According to one or more aspects, the sync field may be translated as an equivalent part of data field with the same duration.

In some embodiments, the number DATA_PAD_LENGTH may be a minimum value among possible values set such that a number of codewords N_CW2 carried in the data field is an integer value. The N_CW2 may have a value in accordance with equation (13), e.g.,

$${N}_{CW 2} = \frac{( EDMG\_LENGTH + DATA\_PAD \_LENGTH ) \cdot 8}{\frac{{L}_{CW}}{ρ} \cdot R} .$$

L_{CW} may be a specified low density parity check (LDPC) codeword length for the PPDU. ρ may be a specified repetition factor for the PPDU. R may be a specified code rate for the PPDU. One, some or all of L_{CW}, ρ and R may be specified in the EDMG-Header-A.

The length SYNC_LENGTH as measured in octets may specify an equivalent number of octets which, upon encoding and modulation in a same manner as octets of the data field, may result in a (integer) number of single carrier symbol blocks which has the same duration as the sync field.

In some embodiments, the sync field may include a number N_SYM_SYNC_SENS of modulation symbols and the number N_SYM_SYNC_SENS relates to the length SYNC_LENGTH via:

$$N\_SYM \_SYNC \_SENS = N\_blk \_SYNC \times 512 ; \qquad Equation ( 5 ) or ( 6 )$$

$${N}_{CW\_SYNC} = ⌊ ( 512 - {N}_{GI} ) \times N\_blk \_SYNC \times N\_CBPS \times {N}_{CB} / {L}_{CW} ⌋ ; and \qquad Equation ( 20 )$$

$$SYNC\_LENGTH = ⌊ {N}_{CW\_SYNC} \cdot \frac{{L}_{CW}}{ρ} \cdot R / 8 ⌋ . \qquad Equation ( 21 )$$

L_{CW} may be a specified low density parity check (LDPC) codeword length for the PPDU. ρ may be a specified repetition factor for the PPDU. R may be a specified code rate for the PPDU. N_{GI} may be a number of symbols in each one of a plurality of guard intervals interspersed with symbol blocks of the data field. N_{CBPS} may be a number of coded bits per constellation symbol and is determined based on a specified modulation and coding scheme (MCS) for the PPDU. N_{CB} may be a number of channels bonded together as the operation spectrum used for transmission of the PPDU. One, some or all of L_{CW}. ρ, R and the MCS may be specified in the EDMG-Header-A.

In some embodiments, Nar may be set to equal 64. N_{GI} may be specified by a GI length field of an L-Header field of the PPDU.

According to another aspect, the method 1300 may be performed by a system. The system may include an IEEE 802.11 EDMG STA (e.g., initiator 1301), and one or more EDMG multi-static sensing STAs (responders 1311 and 1321) to which a multi-static sensing PPDU 1304 is transmitted. The multi-static sensing PPDU 1304 may include one or more fields according to one or more aspects described herein.

According to embodiments of the present disclosure, the PSDU Length field in EDMG multi-static sensing PPDU may have a value, as before, according to:

$$LENGTH = EDMG\_LENGTH + SYNC\_LENGTH \qquad ( 22 )$$

in which EDMG_LENGTH and SYNC_LENGTH correspond to the Data field 314 and Sync field 315, respectively. In various such embodiments, EDMG_LENGTH data may result in an integer number of codewords and an integer number of symbol blocks through the EDMG coding procedure. In some aspects, the SYNC_LENGTH may be set to a value to result in an exact number of codewords and an exact number of symbol blocks. This may be achieved using padding symbols in the sync pad subfield. Such embodiments are described for example with respect to FIG. 14.

Such embodiments focus on the determination of SYNC_LENGTH as expressed above. For example, by following equations (17), (18) and (19), the exact number of equivalent codewords corresponding to Sync field may be calculated as with a modification of (20):

$${N}_{CW\_SYNC} = ( 512 - N\_GI ) \times N\_blk \_SYNC \times N\_CBPS \times {N}_{CB} / {L}_{CW} \qquad ( 23 )$$

According to an aspect, the SYNC_LENGTH to be included in PSDU Length field, which corresponds to the Sync field, may be calculated as:

$$SYNC\_LENGTH = {N}_{CW\_SYNC} \cdot \frac{{L}_{CW}}{ρ} \cdot R / 8 \qquad ( 24 )$$

where SYNC_LENGTH is an integer obtained by setting a minimal value of N_pad_SYM in equation (17).

FIG. 14 illustrates a method for transmitting a multistatic sensing PPDU, according to an aspect. The method 1400 includes generating, by processing electronics in an initiator 1401, a multistatic sensing PPDU 1404. The processing electronics may refer to a processor for example. The processing electronics and the initiator 1401, may each be based on the apparatus 700. In some embodiments the initiator 1401 may be an IEEE 802.11 EDMG station (STA).

The method 1400 may further include sending, by the initiator 1401, the generated multi-static sensing PPDU 1404 to one or more responders 1411 and 1421. A legacy STA 1431 may also receive the multi-static sensing PPDU 1404.

The method my further include sending to a first responder 1411 a report poll 1405 and receiving from the first responder 1411 a first report 1415. The method further includes, sending, by initiator 1401 to the second responder 1421 a second report poll 1406 and receiving from the second responder 1421 a second report 1416.

In some embodiments, the multistatic sensing PPDU 1404 may be an IEEE 802.11 multistatic sensing PPDU, e.g., PPDU 300. The IEEE 802.11 multistatic sensing PPDU 1404 may include a data field carrying a number EDMG_LENGTH of data octets. The IEEE 802.11 multistatic sensing PPDU 1404 may further include a sync field following the data field and having a same duration as a field carrying a length of SYNC_LENGTH data as measured in octets. The sync field may include a number of Sync subfields and a Sync_PAD subfield with N_pad_SYM of padding symbols. The IEEE 802.11 multistatic sensing PPDU 1404 may further include a PSDU Length field included in an EDMG-Header-A of the PPDU. The PSDU Length field may be set by the processing electronics (e.g., a processor) within the initiator 1401 to have a value equal to: LENGTH=EDMG_LENGTH+SYNC_LENGTH.

The length SYNC_LENGTH may be related to the number N_pad_SYM via:

$$N\_blk \_SYNC = ( TRN\_BL \times 18 \times N\_STA + N\_pad \_SYM ) / 512 ; \qquad Equation ( 17 )$$

$${N}_{CW\_SYNC} = ( 512 - {N}_{GI} ) \times N\_blk \_SYNC \times N\_CBPS \times {N}_{CB} / {L}_{CW} ; and \qquad Equation ( 20 )$$

$$SYNC\_LENGTH = {N}_{CW\_SYNC} \cdot \frac{{L}_{CW}}{ρ} \cdot R / 8. \qquad Equation ( 21 )$$

The number N_pad_SYM may be set such that SYNC_LENGTH is an integer value. The TRN_BL may be specified value indicative of a length of Golay sequences used in the PPDU. N_STA may be a number of EDMG multistatic sensing stations (STAs) to which the multistatic sensing PPDU 1404 is transmitted. L_{CW} may be a specified low density parity check (LDPC) codeword length for the PPDU. ρ may be a specified repetition factor for the PPDU. R may be a specified code rate for the PPDU. N_{GI} may be a number of symbols in each one of a plurality of guard intervals interspersed with symbol blocks of the data field. N_{CBPS} may be a number of coded bits per constellation symbol and is determined based on a specified modulation and coding scheme (MCS) for the PPDU. N_{CB} may be a number of channels bonded together as operation spectrum used for transmission of the PPDU. The method may allow for a legacy EDMG STA 1431 to understand the duration of an EDMG multi-static sensing PPDU 1404. The method may further allow for a legacy EDMG STA 1431 to interpret the duration of the Data field and the Sync field in an EDMG multi-static sensing PPDU 1404 as equivalent to the duration of Data field in an EDMG PPDU. The method may further allow for transmission of both data and sensing signals while maintaining backward compatibility and coexistence with legacy EDMG STAS.

In some embodiments, one, some or all of L_{CW}, ρ, R and the MCS may be specified in the EDMG-Header-A. TRN_BL may be indicated by a TRN subfield sequence length field the EDMG-Header-A. The padding symbols may be located in a sync pad subfield forming a last part of the sync field. The number N_pad_SYM is a minimum value among possible values set such that the length SYNC_LENGTH is an integer value.

In some embodiments, the length SYNC_LENGTH as measured in octets may specify an equivalent number of octets which, upon encoding and modulation in a same manner as octets of the data field, would result in a number of modulated symbols having a total duration equivalent to a duration of the sync field.

In some embodiments, N_{GI} may equal to 64. N_{GI} may be specified by a GI length field of an L-Header field of the PPDU.

As may be appreciated, TXVECTOR may refer to a PHY interface between PHY and MAC at a transmitter. In some embodiments, only the TXVECTOR parameters necessary to be used by a receiver (responder) are transmitted through a PPDU over the air. These TXVECTOR parameters may include EDMG_LENGTH, EDMG MCS, LDPC_CW_TYPE, CH_BANDWIDTH, TRN_SEQ_LENGTH, and GI_TYPE, and may be respectively carried in PSDU Length field, MCS field, short/long LDPC field, N_CB field, TRN_BL field, and GI type field, in the preambles of a PPDU.

In some aspects, it is not necessary for a multistatic sensing STA to detect the preamble of a multistatic PPDU. Therefore, in order to decode the Data field carried in a multistatic sensing PPDU, or to perform responder synchronization and sensing measurement, or for a combination of such reasons, the transmitter may need to transmit some TXVECTOR parameters before a transmission of a multistatic sensing PPDU during a multistatic sensing setup phase.

In some aspects, TXVECTOR may be defined based on 802.11 spec, which provides: “The PHY provides an interface to the MAC through an extension of the generic PHY service interface defined in 8.3.4 (Basic service and options). The interface includes TXVECTOR, RXVECTOR, and PHY CONFIG_VECTOR. The TXVECTOR supplies the PHY with per-PPDU transmit parameters.”

FIG. 15 illustrates a method of multi-static sensing, according to another embodiment. The method 1500 includes, initiating, by processing electronics (e.g., a processor) at initiator 1501, transmission of some TXVECTOR parameters through a multi-static sensing setup phase 1530. In some embodiments, the processing electronics and the initiator 1501, may each be based on the apparatus 700. In some embodiments the initiator 1501 may be an IEEE 802.11 EDMG station (STA).

The TXVECTOR parameters may indicate characteristics of an associated IEEE 802.11 multistatic sensing PPDU 1504 to be interpreted by other STAs (e.g., responder 1511 and 1521) participating in a multistatic sensing operation 1540 involving the IEEE 802.11 multistatic sensing PPDU 1504.

In some embodiments, the TXVECTOR parameters may include a PSDU Length field, a MCS field, a short/long LDPC field, a N_CB field, a TRN_BL field, a GI type field, or the like, or a combination thereof. In some embodiments the TXVECTOR parameters may be different from those in EDMG-Header-A.

In some embodiments, the multi-static sensing setup phase 1530 may be similar to the multi-static sensing setup phase 230 of FIG. 2. In some embodiments, initiating transmission of some TXVECTOR parameters may include sending by the initiator 1501 a first request 1502 to a first responder 1511, and receiving by the initiator 1501 a first response 1512 from the first responder 1511. In some embodiments, initiating transmission of some TXVECTOR parameters may further include sending, by the initiator 1501 a second request 1503 to the second responder 1521, and receiving, by the initiator 1501 a second response 1523 from the second responder 1521.

The method 1500 may further include separately initiating, by the processing electronics at initiator 1501, transmission of the IEEE 802.11 multistatic sensing PPDU 1504. In some embodiments, initiating transmission of the IEEE 802.11 multistatic sensing PPDU 1504 may include generating, by the processing electronics, the IEEE 802.11 multistatic sensing PPDU 1504 (which may be similar to the EDMG multi-static PPDU 300). In some embodiments, the IEEE 802.11 multistatic sensing PPDU 1504 may have a PSDU Length field set such that another IEEE 802.11 EDMG STA 1531 unaware of the multistatic sensing will interpret a combination of a data field and a sync field of the IEEE 802.11 multistatic sensing PPDU 1504 to be a single data field.

In some embodiments method 1500 may further include sending, by the initiator 1501, the generated multi-static sensing PPDU 1504 to the one or more responders 1511 and 1521. The method 1500 may further include sending to a first responder 1511 a report poll 1505 and receiving from the first responder 1511 a first report 1515. The method further includes, sending, by initiator 1501 to the second responder 1521 a second report poll 1506 and receiving from the second responder 1521 a second report 1516. The legacy STA 1531 may also receive the multi-static sensing PPDU 1504.

The method 1500 may allow for a legacy EDMG STA 1531 to understand or determine the duration of an EDMG multi-static sensing PPDU 1504. The method 1500 may further allow for a legacy EDMG STA 1531 to interpret the duration of the Data field and the Sync field in an EDMG multi-static sensing PPDU 1504 as equivalent to the duration of Data field in an EDMG PPDU. The method 1500 may further allow for transmission of both data and sensing signals while maintaining backward compatibility and coexistence with legacy EDMG STAS.

In the context of the embodiment of FIG. 15, TXVECTOR may be viewed as a PHY interface between PHY and MAC at a transmitter. Only the TXVECTOR parameters necessarily to be used by a receiver might be transmitted through a PPDU over the air. These TXVECTOR parameters may include EDMG_LENGTH, EDMG MCS, LDPC_CW_TYPE, CH_BANDWIDTH, TRN_SEQ_LENGTH, and GI_TYPE are carried PSDU Length field, MCS field, short/long LDPC field, N_CB field, TRN_BL field, and GI type field, respectively, in the preamble of a PPDU.

It is not necessary for a multistatic sensing STA to detect the preamble of a multistatic PPDU. Therefore, in order to decode the Data field carried in multistatic sensing PPDU, the transmitter might transmit some TXVECTOR parameters before a transmission of a multistatic sensing PPDU during a multistatic sensing setup phase.

As specified in the IEEE 802.11 standard, in relation to the TXVECTOR, the PHY may provide an interface to the MAC through an extension of the generic PHY service interface. The interface includes TXVECTOR, RXVECTOR, and PHY CONFIG_VECTOR. The TXVECTOR supplies the PHY with per-PPDU transmit parameters.

According to another aspect, an IEEE 802.11 EDMG STA may be provided that includes the processing electronics to generate a multistatic sensing PPDU according to one or more aspects described herein.

According to another aspect, a system may be provided that includes an IEEE 802.11 EDMG STA, and one or more EDMG multistatic sensing STAs to which a multistatic sensing PPDU is transmitted. The multistatic sensing PPDU may include one or more fields according to one or more aspects described herein.

According to another aspect, a method, by the processing electronics for an IEEE 802.11 EDMG station (STA) may be provided. The method includes generating an IEEE 802.11 multistatic sensing PPDU for transmission according to one or more aspects. The IEEE 802.11 multistatic sensing PPDU may include one or more fields according to one or more aspects described herein.

According to one or more aspects, the PSDU Length field may be set to ensure that the duration of combined Data field 314 and Sync field 315 in an EDMG multi-static sensing PPDU 300 is well-interpreted as an equivalent duration of Data field 344 in EDMG PPDU 330. Setting the duration of the combined Data field 314 and Sync field 315 to a duration of Data field 344 may allow for co-existence of EDMG sensing with EDMG. Accordingly, both data and sensing signals may be transmitted while maintaining backward compatibility and coexistence with EDMG.

According to an aspect, the PSDU Length field may be set to allow for co-existence in the preamble of EDMG multi-static sensing PDDU that carries data and sensing sounding signals such that both the Data field and the Sync field in EDMG multi-static sensing PDDU are an integer number of SC symbol blocks, respectively, and thus, legacy EDMG STAs can interpret the duration of Data field and Sync field in EDMG multi-static sensing PDDU.

According to an aspect, a new data bit padding procedure may be provided for PSDU data bits before encoding in order to generate an integer number of codewords with EDMG_LENGTH and newly considered DATA_PAD_LENGTH in PSDU Length field in in the preamble of EDMG multi-static sensing PDDU.

According to an aspect, a new SYNC_LENGTH value in PSDU Length field may be set in the preamble of EDMG multi-static sensing PDDU. The SYNC_LENGTH value may be an integer of octets and related to the number of Sync field parameters.

According to an aspect, some TXVECTOR parameters for PSDU data transmission in multi-static sensing PPDU may be exchanged during a sensing (measurement) setup phase. Some parameters such as the value in PSDU Length field in the preamble of EDMG multi-static PPDU may be provided for the purpose of co-existence.

As may be appreciated, in this disclosure, a variable expressed in a first format or notation, e.g., X_Y, should be understood as equivalent to the same variable expressed in a second format or notation, e.g., X_{Y}.

Aspects of the present disclosure can be implemented using electronics hardware, software, or a combination thereof. In some aspects, this may be implemented by one or multiple computer processors executing program instructions stored in memory. In some aspects, the invention is implemented partially or fully in hardware, for example using one or more field programmable gate arrays (FPGAs) or application specific integrated circuits (ASICs) to rapidly perform processing operations.

It will be appreciated that, although specific aspects of the technology have been described herein for purposes of illustration, various modifications may be made without departing from the scope of the technology. The specification and drawings are, accordingly, to be regarded simply as an illustration of the invention as defined by the appended claims, and are contemplated to cover any and all modifications, variations, combinations or equivalents that fall within the scope of the present invention. In particular, it is within the scope of the technology to provide a computer program product or program element, or a program storage or memory device such as a magnetic or optical wire, tape or disc, or the like, for storing signals readable by a machine, for controlling the operation of a computer according to the method of the technology and/or to structure some or all of its components in accordance with the system of the technology.

Acts associated with the method described herein can be implemented as coded instructions in a computer program product. In other words, the computer program product is a computer-readable medium upon which software code is recorded to execute the method when the computer program product is loaded into memory and executed on the microprocessor of the wireless communication device.

Further, each operation of the method may be executed on any computing device, such as a personal computer, server, PDA, or the like and pursuant to one or more, or a part of one or more, program elements, modules or objects generated from any programming language, such as C++, Java, or the like. In addition, each operation, or a file or object or the like implementing each said operation, may be executed by special purpose hardware or a circuit module designed for that purpose.

Through the descriptions of the preceding aspects, the present invention may be implemented by using hardware only or by using software and a necessary universal hardware platform. Based on such understandings, the technical solution of the present invention may be embodied in the form of a software product. The software product may be stored in a non-volatile or non-transitory storage medium, which can be a compact disc read-only memory (CD-ROM), USB flash disk, or a removable hard disk. The software product includes a number of instructions that enable a computer device (personal computer, server, or network device) to execute the methods provided in the aspects of the present invention. For example, such an execution may correspond to a simulation of the logical operations as described herein. The software product may additionally or alternatively include a number of instructions that enable a computer device to execute operations for configuring or programming a digital logic apparatus in accordance with aspects of the present invention.

Although the present invention has been described with reference to specific features and aspects thereof, it is evident that various modifications and combinations can be made thereto without departing from the invention. The specification and drawings are, accordingly, to be regarded simply as an illustration of the invention as defined by the appended claims, and are contemplated to cover any and all modifications, variations, combinations or equivalents that fall within the scope of the present invention.

1. An apparatus in an IEEE 802.11 EDMG station (STA), the apparatus comprising processing electronics configured to generate an IEEE 802.11 multistatic sensing PPDU for transmission, the IEEE 802.11 multistatic sensing PPDU comprising:
a data field carrying a number EDMG_LENGTH of data octets;
a sync field following the data field and having a same duration as a field carrying a length of SYNC_LENGTH data as measured in octets, the sync field including a number of Sync subfields and a Sync_PAD subfield with N_pad_SYM of padding symbols;
a PSDU Length field included in an EDMG-Header-A of the PPDU, the PSDU Length field set by the apparatus to have a value equal to:
$$LENGTH = EDMG\_LENGTH + SYNC\_LENGTH$$
the length SYNC_LENGTH being related to the number N_pad_SYM via equations:
$$N\_blk \_SYNC = ( TRN\_BL \times 18 \times N\_STA + N\_pad \_SYM ) / 512 ;$$
$${N}_{CW\_SYNC} = ( 512 - {N}_{GI} ) \times N\_blk \_SYNC \times N\_CBPS \times {N}_{CB} / {L}_{CW} ;$$
$$SYNC\_LENGTH = {N}_{CW\_SYNC} \cdot \frac{{L}_{CW}}{ρ} \cdot R / 8 ,$$
the number N_pad_SYM being set such that SYNC_LENGTH is an integer value,
wherein:
TRN_BL is specified value indicative of a length of Golay sequences used in the PPDU;
N_STA is a number of EDMG multistatic sensing stations (STAs) to which the multistatic sensing PPDU is transmitted;
L_{CW} is a specified low density parity check (LDPC) codeword length for the PPDU;
ρ is a specified repetition factor for the PPDU;
R is a specified code rate for the PPDU;
N_{GI} is a number of symbols in each one of a plurality of guard intervals interspersed with symbol blocks of the data field;
N_{CBPS} is a number of coded bits per constellation symbol and is determined based on a specified modulation and coding scheme (MCS) for the PPDU; and
N_{CB} is a number of channels bonded together to create a single channel used for transmission of the PPDU.

2. The apparatus of claim 1, wherein one, some or all of L_{CW}, ρ, R and the MCS are specified in the EDMG-Header-A.

3. The apparatus of claim 1, wherein TRN_BL is indicated by a TRN subfield sequence length field the EDMG-Header-A.

4. The apparatus of claim 1, wherein the padding symbols are located in a sync pad subfield forming a last part of the sync field.

5. The apparatus of claim 1, wherein the number N_pad_SYM is a minimum value among possible values set such that the length SYNC_LENGTH is an integer value.

6. The apparatus of claim 1, wherein the length SYNC_LENGTH as measured in octets specifies an equivalent number of octets which, upon encoding and modulation in a same manner as octets of the data field, would result in a number of modulated symbols having a total duration equivalent to a duration of the sync field.

7. The apparatus of claim 1, wherein N_{GI} equals 64.

8. The apparatus of claim 1, wherein N_{GI} is specified by a GI length field of an L-Header field of the PPDU.

9. An IEEE 802.11 EDMG STA comprising the apparatus of claim 1.

10. A system comprising the IEEE 802.11 EDMG STA of claim 9, and one or more EDMG multistatic sensing STAs to which the multistatic sensing PPDU is transmitted.

11. A method comprising, by processing electronics for a IEEE 802.11 EDMG station (STA), generating an IEEE 802.11 multistatic sensing PPDU for transmission, the IEEE 802.11 multistatic sensing PPDU comprising:
a data field carrying a number EDMG_LENGTH of data octets;
a sync field following the data field and having a same duration as a field carrying a length of SYNC_LENGTH data as measured in octets, the sync field including a number of Sync subfields and a Sync_PAD subfield with N_pad_SYM of padding symbols;
a PSDU Length field included in an EDMG-Header-A of the PPDU, the PSDU Length field set by the apparatus to have a value equal to:
$$LENGTH = EDMG\_LENGTH + SYNC\_LENGTH$$
the length SYNC_LENGTH being related to the number N_pad_SYM via equations:
$$N\_blk \_SYNC = ( TRN\_BL \times 18 \times N\_STA + N\_pad \_SYM ) / 512 ;$$
$${N}_{CW\_SYNC} = ( 512 - {N}_{GI} ) \times N\_blk \_SYNC \times N\_CBPS \times {N}_{CB} / {L}_{CW} ;$$
$$SYNC\_LENGTH = {N}_{CW\_SYNC} \cdot \frac{{L}_{CW}}{ρ} \cdot R / 8 ,$$
the number N_pad_SYM being set such that SYNC_LENGTH is an integer value,
wherein:
TRN_BL is specified value indicative of a length of Golay sequences used in the PPDU;
N_STA is a number of EDMG multistatic sensing stations (STAs) to which the multistatic sensing PPDU is transmitted;
L_{CW} is a specified low density parity check (LDPC) codeword length for the PPDU;
ρ is a specified repetition factor for the PPDU;
R is a specified code rate for the PPDU;
N_{GI} is a number of symbols in each one of a plurality of guard intervals interspersed with symbol blocks of the data field;
N_{CBPS} is a number of coded bits per constellation symbol and is determined based on a specified modulation and coding scheme (MCS) for the PPDU; and
N_{CB} is a number of channels bonded together to create a single channel used for transmission of the PPDU.
